(19) United States
(12) Patent Application Publication
(10) Pub. No.: US 2026/0157092 A1
(43) Pub. Date: Jun. 4, 2026

(54) DISPLAY DEVICE

(71) Applicant: LG DISPLAY CO., LTD., Seoul (KR)

(72) Inventors: Youngmin OH, Paju-si (KR); HyunSeung KIM, Paju-si (KR)

(73) Assignee: LG DISPLAY CO., LTD., Seoul (KR)

(21) Appl. No.: 19/246,386

(22) Filed: Jun. 23, 2025

(30) Foreign Application Priority Data
Dec. 3, 2024 (KR) 10-2024-0177422

(51) Int. Cl. H10K 59/80

(52) U.S. Cl. CPC H10K 59/8791

(57) ABSTRACT

A display device can include a display panel having an optical area including a plurality of transmissive areas and a plurality of light emitting areas, and a normal area disposed outside of the optical area and including a plurality of light emitting areas, an optical electronic device disposed under or in a lower portion of the display panel and overlapping with the optical area, and a plurality of lenses disposed in the optical area and overlapping with the plurality of transmissive areas.

### CROSS REFERENCE TO RELATED APPLICATION

This application claims priority to Korean Patent Application No. 10-2024-0177422, filed on Dec. 3, 2024 in the Republic of Korea, the entirety of which is hereby incorporated by reference into the present application as if fully set forth herein.

### BACKGROUND

### Technical Field

The present disclosure relates to electronic devices, and more specifically, to display devices.

### Related Art

As display technology advances, display devices can provide increased functions, such as an image capture function, a sensing function, and the like, as well as an image display function. To provide these functions, a display device may include an optical electronic device, such as a camera, a sensor for detecting an image, and the like.

In order to receive light passing through the front surface of a display device, it may be desirable for such an optical electronic device to be located in an area of the display device where incident light coming through the front surface can be increasingly received and detected. Thus, in such a display, an optical electronic device can be located in a front portion of the display device so that the optical electronic device can be effectively exposed to incident light. To install an optical electronic device in a display device in this configuration, a bezel area of the display device may be increased, or a notch or a hole may be formed in a display area of an associated display panel.

According to this configuration, as an optical electronic device such as a camera, a sensor, and the like for receiving or detecting light being incident through the front surface and performing an intended function is included in a display device, the size of a bezel in the front of the display device can be increased, or a substantial limitation can be imposed on designing a front portion of the display device. Further, in the configuration where a display device includes an optical electronic device, image quality produced by the display device can be degraded due to the structure where the optical electronic device is configured in the display device.

Accordingly, a need exists for a display device having a configuration with an improved light transmissive structure that can allow optical electronic devices positioned beneath or at a lower part of the display panel to receive light effectively without being visible on the front of the display.

### SUMMARY OF THE DISCLOSURE

To address these issues, one or more aspects of the present disclosure can provide a display device that includes a light transmissive structure capable of enabling at least one optical electronic device disposed under, or at a lower portion of, a display panel to normally receive light while not being exposed in the front of the display device.

One or more aspects of the present disclosure can provide a display device that includes a structure where one or more lenses are disposed to overlap with one or more transmissive areas, and is capable of implementing distinct design between transmissive areas and light emitting areas using a light refraction phenomenon, fully using light passing through the transmissive areas, and preventing degradation of selfie images.

One or more aspects of the present disclosure can provide a display device that includes a structure where one or more lenses are disposed to overlap with one or more transmissive areas, and is capable of causing external light to be directed toward the one or more transmissive areas, and thereby reducing or eliminating a degradation of image quality due to image artifacts such as image blur and the like.

One or more aspects of the present disclosure can provide a display device that includes a structure where one or more lenses are disposed to overlap with one or more transmissive areas, and is capable of reducing or eliminating a degradation of image quality, and thereby being driven at reduced power.

According to one or more example embodiments of the present disclosure, a display device can be provided that includes a display panel including an optical area including a plurality of transmissive areas and a plurality of light emitting areas, and a normal area disposed outside of the optical area and including a plurality of light emitting areas, an optical electronic device disposed under, or in a lower portion, of the display panel and overlapping with the optical area, and a plurality of lenses disposed in the optical area and overlapping with the plurality of transmissive areas, respectively.

According to one or more example embodiments of the present disclosure, a display device can be provided that includes a substrate on which a plurality of transmissive areas and a plurality of light emitting areas are disposed, a planarization layer disposed on the substrate, a plurality of light emitting elements disposed in the plurality of light emitting areas on the planarization layer, a first encapsulation layer disposed on the planarization layer and the plurality of light emitting elements, a plurality of lenses disposed on the first encapsulation layer, and overlapping with the plurality of transmissive areas, respectively, and a second encapsulation layer disposed on the first encapsulation layer and the plurality of lenses.

According to one or more aspects of the present disclosure, a display device can be provided that includes a light transmissive structure capable of enabling at least one optical electronic device disposed under, or at a lower portion of, a display panel to normally receive light while not being exposed in the front of the display device.

According to one or more aspects of the present disclosure, a display device can be provided that includes a structure where one or more lenses are disposed to overlap with one or more transmissive areas, and is capable of implementing distinct design between transmissive areas and light emitting areas using a light refraction phenomenon, fully using light passing through the transmissive areas, and preventing degradation of selfie images.

According to one or more aspects of the present disclosure, a display device can be provided that includes a structure where one or more lenses are disposed to overlap with one or more transmissive areas, and is capable of causing external light to be directed toward the one or more transmissive areas, and thereby, reducing or eliminating a degradation of image quality due to image artifacts such as image blur and the like.

According to one or more aspects of the present disclosure, a display device can be provided that includes a structure where one or more lenses are disposed to overlap with one or more transmissive areas, and is capable of reducing or eliminating a degradation of image quality, and thereby, being driven at reduced power.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIGS. 1A, 1B, 1C and 1D illustrate an example display device according to aspects of the present disclosure;

FIG. 2 illustrates an example system configuration of the display device according to aspects of the present disclosure;

FIG. 3 illustrates an example configuration of a display panel according to aspects of the present disclosure;

FIG. 4 illustrates example arrangements of subpixels disposed in a normal area and optical areas according to aspects of the present disclosure;

FIGS. 5A and 5B illustrate example arrangements of signal lines disposed in the display panel according to aspects of the present disclosure;

FIGS. 6 and 7 illustrate example configurations of an optical area in the display panel according to aspects of the present disclosure;

FIG. 8 illustrates example lenses disposed in an optical area, which are implemented using refracting lenses, according to aspects of the present disclosure;

FIG. 9 illustrates example lenses disposed in an optical area, which are implemented using polarizing lenses, according to aspects of the present disclosure;

FIGS. 10A to 10D illustrate example configurations of a plurality of lenses disposed in an optical area, which are implemented using polarizing lenses, according to aspects of the present disclosure;

FIG. 11 illustrates an example light-outputting characteristic of a plurality of lenses disposed in an optical area, which are implemented using polarizing lenses, according to aspects of the present disclosure;

FIG. 12 illustrates an example light-receiving characteristic of a plurality of lenses disposed in an optical area, which are implemented using polarizing lenses, according to aspects of the present disclosure;

FIG. 13 illustrates an example formation of an optical area according to aspects of the present disclosure; and

FIG. 14 illustrates an example stack-up structure of the display device according to aspects of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Advantages and features of the present disclosure, and implementation methods thereof will be clarified through following example embodiments described with reference to the accompanying drawings. The present disclosure can, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents. In the following description, where the detailed description of the relevant known function or configuration can unnecessarily obscure aspects of the present disclosure, a detailed description of such known function or configuration can be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” can be used herein to describe elements of the present disclosure. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts,” “overlaps with,” or the like a second element, it should be interpreted that, not only can the first element “be directly connected or coupled to,” “directly contact,” or “directly overlap with” the second element, but a third element can also be “interposed” between the first and second elements, or the first and second elements can “be connected or coupled to”, “contact,” “overlap with,” or the like each other via a fourth element. Here, the second element can be included in at least one of two or more elements that “are connected or coupled to”, “contact,” “overlap with,” or the like each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom,” “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, and the like) include a tolerance or error range that can be caused by various factors (e.g., process factors, internal or external impact, noise, and the like) even when a relevant description is not specified. Further, the term “can” fully encompasses all the meanings of the term “may.” The features of various embodiments of the present disclosure can be partially or entirely coupled to or combined with each other and can be interlocked and operated in technically various ways, and the embodiments can be carried out independently of or in association with each other.

In the following description, various example aspects of the present disclosure are described in detail with reference to the accompanying drawings. With respect to reference numerals to elements of each of the drawings, the same elements can be illustrated in other drawings, and like reference numerals can refer to like elements unless stated otherwise. The same or similar elements can be denoted by the same reference numerals even though they are depicted in different drawings. In addition, for convenience of description, a scale, dimension, size, and thickness of each of the elements illustrated in the accompanying drawings can be different from an actual scale, dimension, size, and thickness, and thus, aspects of the present disclosure are not limited to a scale, dimension, size, and thickness illustrated in the drawings.

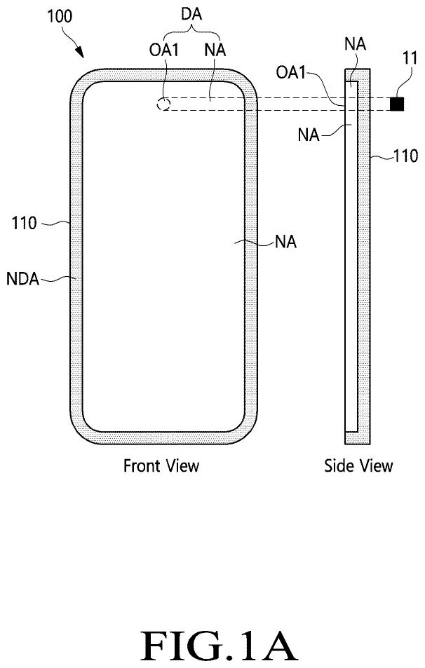

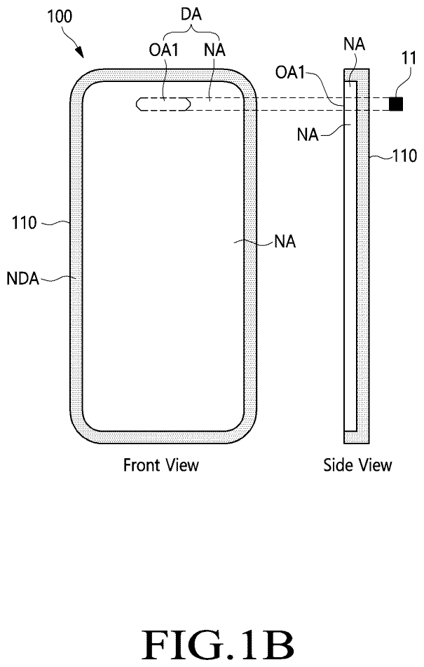

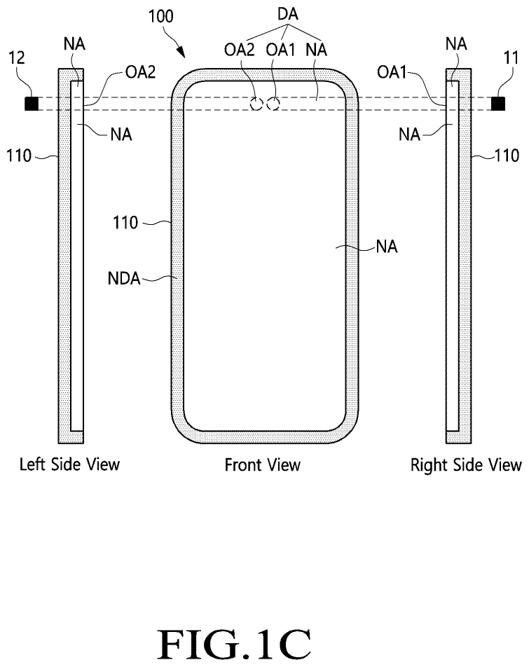

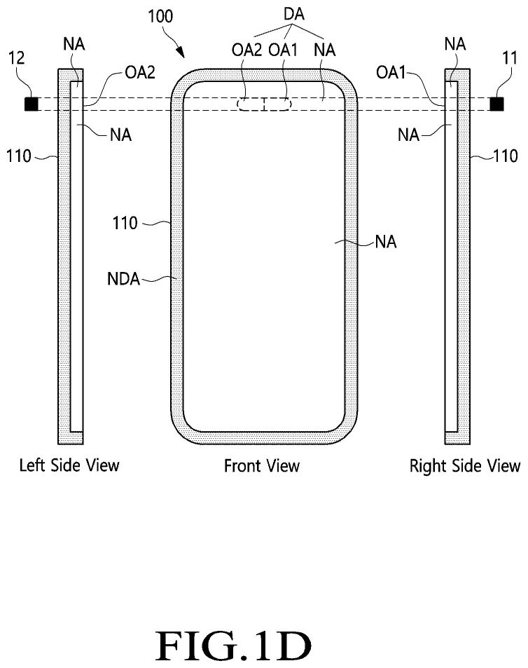

FIGS. 1A to 1D illustrate an example display device according to aspects of the present disclosure.

Referring to FIGS. 1A to 1D, in one or more example embodiments, the display device 100 can include a display panel 110 for displaying images, and one or more optical electronic devices (11 and/or 12).

The display panel 110 can include a display area DA in which images can be displayed and a non-display area NDA in which an image is not displayed.

A plurality of subpixels can be disposed in the display area DA, and several types of signal lines for driving the plurality of subpixels can be disposed therein.

The non-display area NDA can be an area outside of the display area DA. Several types of signal lines can be disposed in the non-display area NDA, and several types of driving circuits can be connected thereto. At least a portion of the non-display area NDA can be bent to be invisible in front of the display device 100 or can be covered by a case or housing of the display device 100. The non-display area NDA can be also referred to as a non-active area, bezel, or bezel area.

Referring to FIGS. 1A to 1D, in one or more aspects, the one or more optical electronic devices (11 and/or 12) included in the display device 100 can be located under, or at a lower portion of, the display panel 110 (an opposite side to the viewing surface thereof).

Light can enter the front surface (the viewing surface) of the display panel 110, pass through the display panel 110, reach one or more optical electronic devices (11 and/or 12) located under, or in the lower portion of, the display panel 110 (the opposite side of the viewing surface).

The one or more optical electronic devices (11 and/or 12) can be devices capable of receiving or detecting light passing through the display panel 110 and perform a predefined function based on the received light. For example, the one or more optical electronic devices (11 and/or 12) can include one or more of the following: an image capture device such as a camera (an image sensor), and/or the like; or a sensor such as a proximity sensor, an illuminance sensor, and/or the like.

Referring to FIGS. 1A to 1D, in one or more aspects, the display area DA of the display panel 110 can include one or more optical areas (OA1 and/or OA2) and a normal area NA. Herein, the term “normal area” NA is an area that while being present in the display area DA, does not overlap with one or more optical electronic devices (11 and/or 12) and can also be referred to as a non-optical area. According to an embodiment, the “normal area” NA of the display can be referred to as a standard pixel area, a general display area or a non-optical area of the display, etc.

The one or more optical areas (OA1 and/or OA2) can be one or more areas respectively overlapping the one or more optical electronic devices (11 and/or 12) in a cross-sectional view of the display panel 110.

Referring to FIG. 1A, in one or more aspects, the display area DA can include a first optical area OA1 and a normal area NA. In this configuration, at least a portion of the first optical area OA1 can overlap with a first optical electronic device 11 (e.g., a camera or sensor, etc.).

FIG. 1A illustrates a structure in which the first optical area OA1 has a circular shape, but the shape of the first optical area OA1 according to aspects of the present disclosure is not limited thereto.

For example, as illustrated in FIG. 1B, the first optical area OA1 can have an octagonal shape, or various polygonal shapes.

Referring to FIG. 1C, in one or more example embodiments, the display area DA can include a first optical area OA1, a second optical area OA2, and a normal area NA. In this configuration, a portion of the normal area NA can be present between the first optical area OA1 and the second optical area OA2. At least a portion of the first optical area OA1 can overlap with the first optical electronic device 11, and at least a portion of the second optical area OA2 can overlap with a second optical electronic device 12.

Referring to FIG. 1D, in one or more aspects, the display area DA can include a first optical area OA1, a second optical area OA2, and a normal area NA. In this configuration, the normal area NA may not be present between the first optical area OA1 and the second optical area OA2. For example, the first optical area OA1 and the second optical area OA2 can contact each other (e.g., directly contact each other). In this example, at least a portion of the first optical area OA1 can overlap with the first optical electronic device 11, and at least a portion of the second optical area OA2 can overlap with the second optical electronic device 12.

In one or more aspects, the one or more optical areas (OA1 and/or OA2) included in the display panel 110 or the display device 100 can be desirable to include both an image display structure and a light transmissive structure. For example, since the one or more optical areas (OA1 and/or OA2) are a portion of the display area DA, therefore, it can be desirable that subpixels for displaying an image are disposed in the one or more optical areas (OA1 and/or OA2). Further, to enable the one or more optical electronic devices (11 and/or 12) to fully receive light, the one or more optical areas (OA1 and/or OA2) can be desirable to include a light transmissive structure.

Hereinafter, the image display structure can be referred to as a light emitting area, and the light transmissive structure can be referred to as a transmissive area.

It should be noted that even though the one or more optical electronic devices (11 and/or 12) are required to receive light, the one or more optical electronic devices (11 and/or 12) can be located under, or at a lower portion of, the display panel 110 (e.g., on an opposite side of the viewing surface thereof). Accordingly, in this configuration, the one or more optical electronic devices (11 and/or 12) can be configured to receive light passing through the display panel 110.

The one or more optical electronic devices (11 and/or 12) may not be exposed to the front surface (viewing surface) of the display panel 110, and thus, when a user views the front surface of the display device 100, the one or more optical electronic devices (11 and/or 12) can be invisible to the user or no perceivable.

The first optical electronic device 11 can be, for example, a camera, and the second optical electronic device 12 can be, for example, a sensor. The sensor can be a proximity sensor, an illuminance sensor, an infrared sensor, and/or the like. In one or more aspects, the camera can be a camera lens, an image sensor, or a unit including at least one of the camera lens and the image sensor, and the sensor can be an infrared sensor capable of detecting infrared light.

In one or more aspects, the first optical electronic device 11 can be a sensor, and the second optical electronic device 12 can be a camera.

Hereinafter, for convenience of description, discussions are provided based on examples where the first optical electronic device 11 is a camera, and the second optical electronic device 12 is a sensor. It should be, however, understood that the scope of the present disclosure includes examples where the first optical electronic device 11 is the sensor, and the second optical electronic device 12 is the camera. The camera can be, for example, a camera lens, an image sensor, or a unit including at least one of the camera lens and the image sensor.

In an example where the first optical electronic device 11 is a camera, the camera can be located under, or at a lower portion of, the display panel 110, and be a front camera capable of capturing objects or images in a front direction of the display panel 110. Accordingly, a user can capture an image or object through the camera that is invisible on the viewing surface while looking at the viewing surface of the display panel 110.

It should be noted here that the normal area NA and the one or more optical areas (OA1 and/or OA2) included in the display area DA in each of FIGS. 1A to 1D are areas capable of presenting images, and the normal area NA is an area where a light transmissive structure need not be implemented, but the one or more optical areas (OA1 and/or OA2) are areas where a light transmissive structure need be implemented. Thus, in one or more aspects, the normal area NA can be an area where a light transmissive structure is not implemented or included, and the one or more optical areas (OA1 and/or OA2) can be areas in which a light transmissive structure is implemented or included.

Accordingly, the one or more optical areas (OA1 and/or OA2) can have a transmittance greater than or equal to a predetermined level, e.g., a relatively high transmittance, and the normal area NA can have a transmittance less than the predetermined level or not have light transmittance (e.g., be opaque).

For example, the one or more optical areas (OA1 and/or OA2) can have a resolution, a subpixel arrangement structure, the number of subpixels per unit area, an electrode structure, a line structure, an electrode arrangement structure, a line arrangement structure, or/and the like different from that/those of the normal area NA.

In one or more aspects, the number of subpixels per unit area in the one or more optical areas (OA1 and/or OA2) can be less than the number of subpixels per unit area in the normal area NA. For example, the resolution of the one or more optical areas (OA1 and/or OA2) can be lower than that of the normal area NA. Here, the number of subpixels per unit area can be a unit for measuring resolution, for example, referred to as pixels (or subpixels) per inch (PPI), which represents the number of pixels (or subpixels) within 1 inch. Also, according to an embodiment, the subpixels in the one or more optical areas can have a different size or shape than the subpixels in the normal area. For example, the subpixels in the one or more optical areas can be larger than the subpixels in the normal area but spaced farther apart etc., but embodiments are not limited thereto.

In one or more aspects, in each of FIGS. 1A to 1D, the number of subpixels per unit area in the first optical areas OA1 can be less than the number of subpixels per unit area in the normal area NA. In one or more aspects, in each of FIGS. 1C and 1D, the number of subpixels per unit area in the second optical areas OA2 can be greater than or equal to the number of subpixels per unit area in the first optical areas OA1.

In each of FIGS. 1A to 1D, the first optical area OA1 can have various shapes, such as a circle, an ellipse, a quadrangle, a hexagon, an octagon or the like. In each of FIGS. 1C and 1D, the second optical area OA2 can have various shapes, such as a circle, an ellipse, a quadrangle, a hexagon, an octagon or the like. The first optical area OA1 and the second optical area OA2 can have the same or substantially or nearly the same shape, or different shapes.

Referring to FIG. 1D, in the example where the first optical area OA1 and the second optical area OA2 contact each other (e.g., directly contact each other), the whole optical area including the first optical area OA1 and the second optical area OA2 can also have various shapes, such as a circle, an ellipse, a quadrangle, a hexagon, an octagon or the like.

Hereinafter, for convenience of descriptions related to shapes of the optical areas (OA1 and OA2), each of the first optical area OA1 and the second optical area OA2 is considered to have a circular shape. It should be, however, understood that the scope of the present disclosure includes examples where at least one of the first optical area OA1 and the second optical area OA2 have a shape other than a circular shape.

The display device 100 having a structure in which the first optical electronic device 11 such as a camera, and the like. is located under, or at a lower portion of, the display panel 100 without being exposed to the outside can be referred to as a display in which under-display camera (UDC) technology is implemented.

According to this structure, the display device 100 can provide an advantage of preventing a size of the display area DA from being reduced because a notch or a camera hole for exposing a camera need not be formed in the display panel 110. For example, the use of a hole or notch for a camera can be avoided and an entire notch-free image screen can be provided to the user.

Indeed, since a notch or a camera hole for camera exposure need not be formed in the display panel 110, the display device 100 can provide further advantages of reducing a size of a bezel area, and improving the degree of freedom in design because such limitations to the design are removed.

Although the one or more optical electronic devices (11 and/or 12) are located under, or at a lower portion of, the display panel 110 of the display device 100 (e.g., hidden or not to be exposed to the outside), the one or more optical electronic devices (11 and/or 12) are used to perform normal predefined functionalities, and thus, receive or detect light.

Further, although one or more optical electronic devices (11 and/or 12) in the display device 100 are located under, or at a lower portion of, the display panel 110 to be hidden and located to be overlap with the display area DA, it is desirable for image display to be normally performed in the one or more optical areas (OA1 and/or OA2) overlapping with the one or more optical electronic devices (11 and/or 12) in the display area DA. Thus, in one or more aspects, even though one or more optical electronic devices (11 and/or 12) are located on the back of the display panel, images can be displayed in a normal manner (e.g., without a reduction in image quality) in the one or more optical areas (OA1 and/or OA2) overlapping with the one or more optical electronic devices (11 and/or 12) in the display area DA.

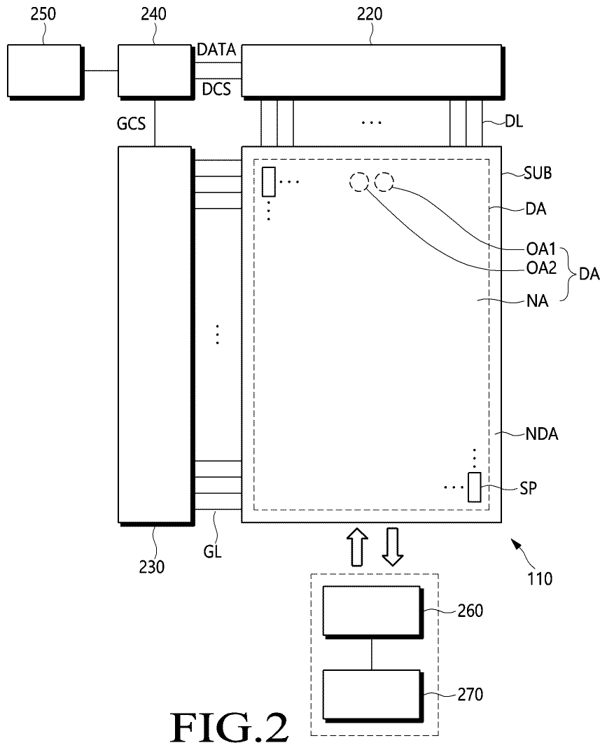

FIG. 2 illustrates an example system configuration of the display device 100 according to aspects of the present disclosure.

Referring to FIG. 2, the display device 100 can include the display panel 110 and at least one display driving circuit as components for displaying one or more images.

The at least one display driving circuit can be a circuit for driving the display panel 110, and include a data driving circuit 220, a gate driving circuit 230, a controller 240, and other circuit components.

The display panel 110 can include the display area DA in which images can be displayed and the non-display area NDA in which an image is not displayed. The non-display area NDA can be an area outside of the display area DA, and can also be referred to as a non-active area or a bezel area. All or at least a portion of the non-display area NDA can be an area visible from the front surface of the display device 100, or an area that is bent and invisible from the front surface of the display device 100.

The display panel 110 can include a substrate SUB and a plurality of subpixels SP disposed on the substrate SUB. The display panel 110 can further include several types of signal lines to drive the plurality of subpixels SP.

In one or more aspects, the display device 100 herein can be a liquid crystal display device, or the like, or a self-emissive display device in which light is emitted from the display panel 110 itself. In an example where the display device 100 is the self-emissive display device, each of a plurality of subpixels SP included in the display panel 110 can include a light emitting element.

For example, the display device 100 according to aspects of the present disclosure can be an organic light emitting display device in which light emitting elements are implemented using organic light emitting diodes (OLED). In another example, the display device 100 according to aspects of the present disclosure can be an inorganic light emitting display device in which light emitting elements are implemented using inorganic material-based light emitting diodes. In further another embodiment, the display device 100 according to aspects of the present disclosure can be a quantum dot display device in which the light emitting element is implemented using quantum dots, which are self-emission semiconductor crystals.

The structure of each of the plurality of subpixels SP can be differently configured or designed according to types of the display devices 100. For example, when the display device 100 is a self-emissive display device including self-emissive subpixels SP, each subpixel SP can include a self-emissive light emitting element, one or more transistors, and one or more capacitors.

In one or more aspects, several types of signal lines arranged in the display device 100 can include, for example, a plurality of data lines DL for carrying data signals (which can be referred to as data voltages or image signals), a plurality of gate lines GL for carrying gate signals (which can be referred to as scan signals), and the like.

The plurality of data lines DL and the plurality of gate lines GL can intersect each other. Each of the plurality of data lines DL can extend in a first direction. Each of the plurality of gate lines GL can extend in a second direction different from the first direction.

For example, the first direction can be the column or vertical direction, and the second direction can be the row or horizontal direction. In another example, the first direction can be the row or horizontal direction, and the second direction can be the column or vertical direction.

The data driving circuit 220 can be a circuit for driving the plurality of data lines DL, and can supply data signals to the plurality of data lines DL. The gate driving circuit 230 can be a circuit for driving the plurality of gate lines GL, and can supply gate signals to the plurality of gate lines GL.

The controller 240 can be a device for controlling the data driving circuit 220 and the gate driving circuit 230, and can control driving times for the plurality of data lines DL and driving times for the plurality of gate lines GL.

The controller 240 can supply a data control signal DCS to the data driving circuit 220 to control the data driving circuit 220, and supply a gate control signal GCS to the gate driving circuit 230 to control the gate driving circuit 230.

The controller 240 can receive image data input from a host system 250 and supply image data DATA readable by the data driving circuit 220 based on the input image data to the data driving circuit 220.

The data driving circuit 220 can supply data signals to the plurality of data lines DL according to driving timing control of the controller 240.

The data driving circuit 220 can receive digital image data DATA from the controller 240, convert the received image data DATA into analog data signals, and output the resulting analog data signals to the plurality of data lines DL.

The gate driving circuit 230 can supply gate signals to the plurality of gate lines GL according to timing control of the controller 240. The gate driving circuit 230 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more aspects, the data driving circuit 220 can be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique.

In one or more aspects, the gate driving circuit 230 can be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. In one or more aspects, the gate driving circuit 230 can be disposed in the non-display area NDA of the display panel 110 by a gate-in-panel (GIP) technique. The gate driving circuit 230 can be disposed on the substrate, or connected to the substrate. In an example where the gate driving circuit 230 is implemented by the GIP technique, the gate driving circuit 230 can be disposed in the non-display area NDA of the substrate SUB. The gate driving circuit 230 can be connected to the substrate SUB in an example where the gate driving circuit 230 is implemented by the chip-on-glass (COG) technique, the chip-on-film (COF) technique, or the like.

In one or more aspects, at least one of the data driving circuit 220 and the gate driving circuit 230 can be disposed in the display area DA of the display panel 110. For example, at least one of the data driving circuit 220 and the gate driving circuit 230 can be disposed not to overlap subpixels SP, or disposed to overlap one or more, or all, of the subpixels SP, or at least respective one or more portions of one or more subpixels.

In one or more aspects, the data driving circuit 220 can be disposed in, and/or electrically connected to, but not limited to, only one side or edge (e.g., an upper portion or a lower portion) of the display panel 110. In one or more aspects, the data driving circuit 220 can be located in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

In one or more aspects, the gate driving circuit 230 can be located in, and/or electrically connected to, but not limited to, one side or edge (e.g., a left portion or a right portion) of the display panel 110. In one or more aspects, the gate driving circuit 230 can be located in, and/or electrically connected to, but not limited to, two sides or edges (e.g., a left portion and a right portion) of the panel 110 or at least two of four sides or edges (e.g., an upper portion, a lower portion, the left portion, and the right portion) of the panel 110 according to driving schemes, panel design schemes, or the like.

The controller 240 can be implemented in a separate component from the data driving circuit 220, or integrated with the data driving circuit 220, so that the controller 240 and the data driving circuit 220 can be implemented in a single integrated circuit.

The controller 240 can be a timing controller used in the display technology or a control device capable of additionally performing other control functionalities in addition to the function of the timing controller. In one or more aspects, the controller 240 can be one or more other control circuits different from the timing controller, or a circuit or component in the control device. The controller 240 can be implemented using various circuits or electronic components such as an integrated circuit (IC), a field programmable gate array (FPGA), an application specific integrated circuit (ASIC), a processor, and/or the like.

The controller 240 can be mounted on a printed circuit board, a flexible printed circuit, or the like, and can be electrically connected to the data driving circuit 220 and the gate driving circuit 230 through the printed circuit board, the flexible printed circuit, and/or the like.

The controller 240 can transmit signals to, and receive signals from, the data driving circuit 220 via one or more predetermined interfaces. For example, such interfaces can include a low voltage differential signaling (LVDS) interface, an embedded clock point-point interface (EPI), a serial peripheral interface (SPI), and the like.

In one or more aspects, in order to further provide a touch sensing function as well as an image display function, the display device 100 can include at least one touch sensor, and a touch sensing circuit capable of detecting whether a touch event occurs by a touch object such as a finger, a pen, or the like, or of detecting a corresponding touch position, by sensing the touch sensor.

The touch sensing circuit can include a touch driving circuit 260 capable of generating and providing touch sensing data by driving and sensing the touch sensor, a touch controller 270 capable of detecting the occurrence of a touch event or detecting a touch position (or touch coordinates) using the touch sensing data, and one or more other components.

The touch sensor can include a plurality of touch electrodes. The touch sensor can further include a plurality of touch lines for electrically connecting the plurality of touch electrodes to the touch driving circuit 260.

The touch sensor can be implemented in the form of a touch panel outside of the display panel 110 or be integrated inside of the display panel 110. The touch sensor disposed outside of the display panel 110 can be referred to as an add-on type touch sensor. In the example where the add-on type of touch sensor is disposed in the display device 100, the touch panel and the display panel 110 can be separately manufactured and combined in an assembly process. The add-on type of touch panel can include a touch panel substrate and a plurality of touch electrodes disposed on the touch panel substrate.

In the example where the touch sensor is integrated inside of the display panel 110, the touch sensor can be formed on the substrate SUB together with signal lines and electrodes related to display driving during a process of manufacturing the display panel 110.

The touch driving circuit 260 can supply a touch driving signal to at least one of a plurality of touch electrodes, and sense at least one of the plurality of touch electrodes to generate touch sensing data.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on a capacitance between one or more touch electrodes and an object such as a finger, a pen, and/or the like.

According to the self-capacitance sensing technique, each of a plurality of touch electrodes can serve as both a driving touch electrode and a sensing touch electrode. The touch driving circuit 260 can drive all, or one or more, of the plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes.

According to the mutual-capacitance sensing technique, a plurality of touch electrodes can be divided into driving touch electrodes and sensing touch electrodes. The touch driving circuit 260 can drive the driving touch electrodes and sense the sensing touch electrodes.

In one or more aspects, the touch driving circuit 260 and the touch controller 270, which are included in the touch sensing circuit, can be implemented in separate devices or in one device. In one or more aspects, the touch driving circuit 260 and the data driving circuit 220 can be implemented in separate devices or in one device.

The display device 100 can further include a power supply circuit for supplying several types of power to the display driving circuit and/or the touch sensing circuit.

In one or more aspects, the display device 100 can be a mobile terminal such as a smart phone, a tablet, or the like, or a monitor, a television (TV), or the like. Further, the display device 100 can be configured with various types, sizes, and shapes to display information or images. For example, the display device 100 can be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

As described above, the display area DA of the display panel 110 can include the normal area NA and the one or more optical areas (OA1 and/or OA2) as illustrated in FIGS. 1A to 1D.

The normal area NA and the one or more optical areas (OA1 and/or OA2) can be areas where images can be displayed. It should be noted here that the normal NA can be an area in which a light transmissive structure need not be implemented, and the one or more optical areas (OA1 and/or OA2) can be areas in which a light transmissive structure will be implemented.

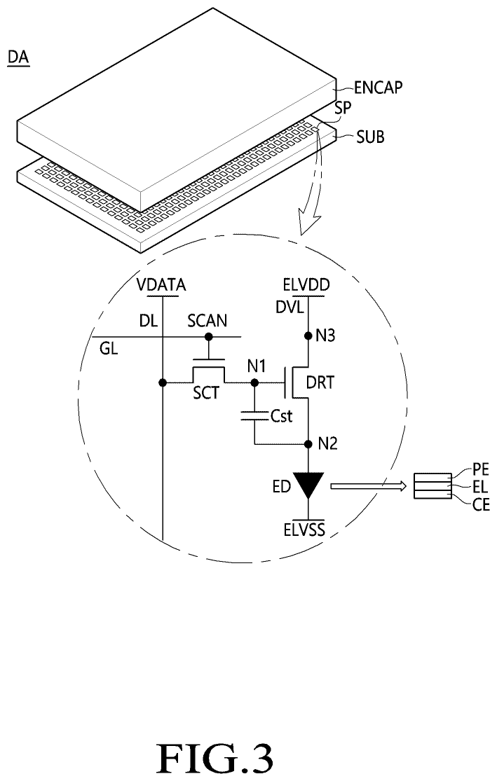

FIG. 3 illustrates an example configuration of the display panel 110 according to aspects of the present disclosure.

Referring to FIG. 3, in one or more example embodiments, each of subpixels SP disposed in the normal area NA, the first optical area OA1, and the second optical area OA2 included in the display area DA of the display panel 110 can include a light emitting element ED disposed on the substrate SUB and disposed in a light emitting area, a driving transistor DRT for driving the light emitting element ED, a scan transistor SCT for transferring a data voltage VDATA to a first node N1 of the driving transistor DRT, a storage capacitor Cst for maintaining a voltage at an approximate constant level during one frame or a period of the one frame, and the like.

The driving transistor DRT can include the first node N1 to which a data voltage is applied, a second node N2 electrically connected to the light emitting element ED, and a third node N3 to which a driving voltage ELVDD delivered through a driving voltage line DVL is applied.

The first node N1 of the driving transistor DRT can be the gate node of the driving transistor DRT, and can be electrically connected to the source node or drain node of the scan transistor SCT.

The second node N2 of the driving transistor DRT can be the source node or drain node of the driving transistor DRT, and can also be electrically connected to a pixel electrode PE of the light emitting element ED.

The third node N3 of the driving transistor DRT can be the drain node or the source node of the driving transistor DRT.

The storage capacitor Cst can be connected between the first node N1 and the second node N2 of the driving transistor DRT. The storage capacitor Cst can store the amount of electric charge corresponding to a voltage difference between both terminals and maintain the voltage difference between both terminals for a predetermined frame time. According to this configuration, the corresponding subpixel SP can emit light for the predetermined frame time.

The scan transistor SCT can be controlled by a gate signal, and can be connected between the first node N1 of the driving transistor DRT and a data line DL.

The scan transistor SCT can be turned on by a gate signal having a turn-on level voltage delivered through a gate line GL, and transfer a data voltage VDATA delivered through the data line DL to the first node N1 of the driving transistor DRT.

Each of the driving transistor DRT and the scan transistor SCT can be an n-type transistor or a p-type transistor.

In an example where the scan transistor SCT is an n-type transistor, the turn-on level voltage of the gate signal can be a high level voltage. In another example where the scan transistor SCT is a p-type transistor, the turn-on level voltage of the gate signal can be a low level voltage.

The light emitting element ED can include a pixel electrode PE, an emission layer EL, and a common electrode CE. A base voltage ELVSS can be applied to the common electrode CE.

For example, the pixel electrode PE can be an anode electrode, and the common electrode CE can be a cathode electrode. In another example, the pixel electrode PE can be a cathode electrode, and the common electrode CE can be an anode electrode. Hereinafter, for convenience of explanation, discussions can be provided based on examples where the pixel electrode PE is an anode electrode, and the common electrode CE is a cathode electrode.

The light emitting element ED can be, for example, an organic light emitting diode (OLED), an inorganic light emitting diode, a quantum dot light emitting element, or the like. In an example where the organic light emitting diode is used as the light emitting element ED, the emission layer EL thereof can include an organic emission layer including an organic material.

The storage capacitor Cst can be an external capacitor intentionally designed to be located outside of the driving transistor DRT, other than an internal capacitor, such as a parasitic capacitor (e.g., a Cgs or a Cgd), that can be formed between the gate node and the source node (or the drain node) of the driving transistor DRT.

Since circuit elements (e.g., in particular, a light emitting element ED) in each subpixel SP are vulnerable to external moisture or oxygen, an encapsulation layer ENCAP can be disposed in the display panel PNL to prevent the external moisture or oxygen from penetrating into the circuit elements (e.g., in particular, the light emitting element ED). The encapsulation layer ENCAP can be disposed on the light emitting element ED such that is covers the light emitting element ED.

It should be noted that the configuration of the subpixel SP shown in FIG. 3 is merely one example of subpixel configurations that can be applied. For example, the subpixel SP can be variously configured according design requirements, and further include one or more transistors, and/or further include one or more capacitors.

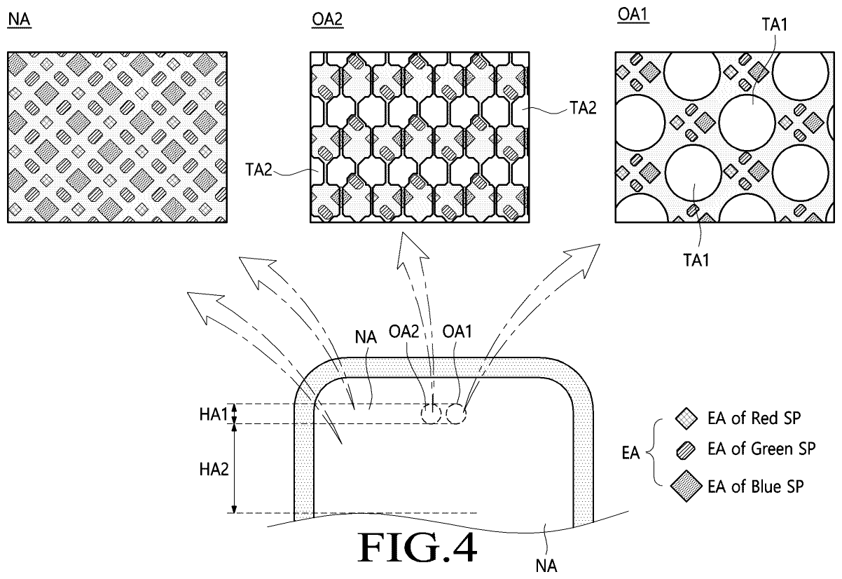

FIG. 4 illustrates example arrangements of subpixels disposed in a normal area (e.g., the normal area NA of FIGS. 1A to 1D) and optical areas (e.g., the first and/or second optical areas (OA1 and/or OA2) of FIGS. 1A to 1D) according to aspects of the present disclosure.

Referring to FIG. 4, in one or more example embodiments, a plurality of subpixels SP can be disposed in each of the normal area NA, the first optical area OA1, and the second optical area OA2 included in the display area DA.

The plurality of subpixels SP can include, for example, at least one red subpixel (Red SP) emitting red light, at least one green subpixel (Green SP) emitting green light, and at least one blue subpixel (Blue SP) emitting blue light.

Accordingly, each of the normal area NA, the first optical area OA1, and the second optical area OA2 can include light emitting areas EA of red subpixels (Red SP), and light emitting areas EA of green subpixels (Green SP), and light emitting areas EA of blue subpixels (Blue SP).

Referring to FIG. 4, the normal area NA may not include a transmissive area (e.g., a light transmissive structure), but include light emitting areas EA.

In contrast, it can be desirable that the first optical area OA1 and the second optical area OA2 include both a plurality of light emitting areas EA and a plurality of transmissive areas.

Accordingly, in one or more aspects, the first optical area OA1 can include a plurality of light emitting areas EA and a plurality of first transmissive areas TA1, and the second optical area OA2 can include a plurality of light emitting areas EA and a plurality of second transmissive areas TA2.

The plurality of light emitting areas EA and the plurality of transmissive areas (TA1 and/or TA2) can be distinct according to whether light is allowed to be transmitted. For example, the plurality of light emitting areas EA can be areas not allowing light to be transmitted (e.g., not allowing light to be transmitted to the back of the display panel), and the plurality of transmissive areas (TA1 and/or TA2) can be areas allowing light to be transmitted (e.g., allowing light to be transmitted to the back of the display panel). For example, the transmissive areas (TA1 and/or TA2) can be see-through areas of the screen.

Further, the plurality of light emitting areas EA and the plurality of transmissive areas (TA1 and/or TA2) can be also distinct according to whether or not a specific metal layer is included. For example, the cathode electrode CE as illustrated in FIG. 3 can be disposed in the plurality of light emitting areas EA, and the cathode electrode CE may not be disposed in the plurality of transmissive areas (TA1 and/ TA2). For example, a light shield layer can be disposed in the plurality of light emitting areas EA, and a light shield layer may not be disposed in the plurality of transmissive areas (TA1 and/or TA2).

Since the first optical area OA1 includes the first transmissive areas TA1 and the second optical area OA2 includes the second transmissive areas TA2, both of the first optical area OA1 and the second optical area OA2 can be areas through which light can be transmitted.

In one or more aspects, a transmittance (a degree of transmission) of the first optical area OA1 and a transmittance (a degree of transmission) of the second optical area OA2 can be substantially the same.

In this configuration, the first transmissive areas TA1 of the first optical area OA1 and the second transmissive areas TA2 of the second optical area OA2 can have substantially the same shape or size. In one or more aspects, even when the first transmissive areas TA1 of the first optical area OA1 and the second transmissive areas TA2 of the second optical area OA2 have different shapes or sizes, a ratio of the first transmissive areas TA1 to the first optical area OA1 and a ratio of the second transmissive areas TA2 to the second optical area OA2 can be substantially the same. For example, each of the first transmissive areas TA1 can have the same shape and size, and each of the second transmissive areas TA2 can have the same shape and size.

In one or more aspects, a transmittance (a degree of transmission) of the first optical area OA1 and a transmittance (a degree of transmission) of the second optical area OA2 can be different from each other.

In this configuration, at least one of the plurality of first transmissive areas TA1 of the first optical area OA1 and at least one of the plurality of first transmissive areas TA1 of the second optical area OA2 can have shapes or sizes different from each other. In one or more aspects, even when the first transmissive areas TA1 of the first optical area OA1 and the second transmissive areas TA2 of the second optical area OA2 have substantially the same shape or size, a ratio of the first transmissive areas TA1 to the first optical area OA1 and a ratio of the second transmissive areas TA2 to the second optical area OA2 can be different from each other.

In one or more aspects, in the example where the first optical electronic device 11 overlapping with the first optical area OA1 is a camera, and the second optical electronic device 12 overlapping with the second optical area OA2 is a sensor for detecting images, the camera may need a greater amount of light than the sensor.

Thus, the transmittance (degree of transmission) of the first optical area OA1 can be greater than the transmittance (degree of transmission) of the second optical area OA2.

For example, at least one of the first transmissive areas TA1 of the first optical area OA1 can have a size greater than at least one of the second transmissive areas TA2 of the second optical area OA2. In one or more aspects, even when the first transmissive areas TA1 of the first optical area OA1 and the second transmissive areas TA2 of the second optical area OA2 have substantially the same size, a ratio of the first transmissive areas TA1 to the first optical area OA1 can be greater than a ratio of the second transmissive areas TA2 to the second optical area OA2.

The transmissive areas (TA1, TA2) as shown in FIG. 4 can be referred to as transparent areas, see-through areas or open areas and the term transmittance can be referred to as transparency.

Further, in the discussion that follows, it is assumed that the first optical area OA1 and the second optical area OA2 are located in an upper edge of the display area DA of the display panel 110, and are disposed adjacent to each other in left and right directions, for example, being disposed in a direction in which the upper edge extends, as illustrated in FIG. 4, unless explicitly stated otherwise.

Referring to FIG. 4, a horizontal display area in which the first optical area OA1 and the second optical area OA2 are disposed can be referred to as a first horizontal display area HA1, and another horizontal display area in which the first optical area OA1 and the second optical area OA2 are not disposed can be referred to as a second horizontal display area HA2.

Referring to FIG. 4, the first horizontal display area HA1 can include a portion of the normal area NA, the first optical area OA1, and the second optical area OA2. The second horizontal display area HA2 can include only the normal area NA.

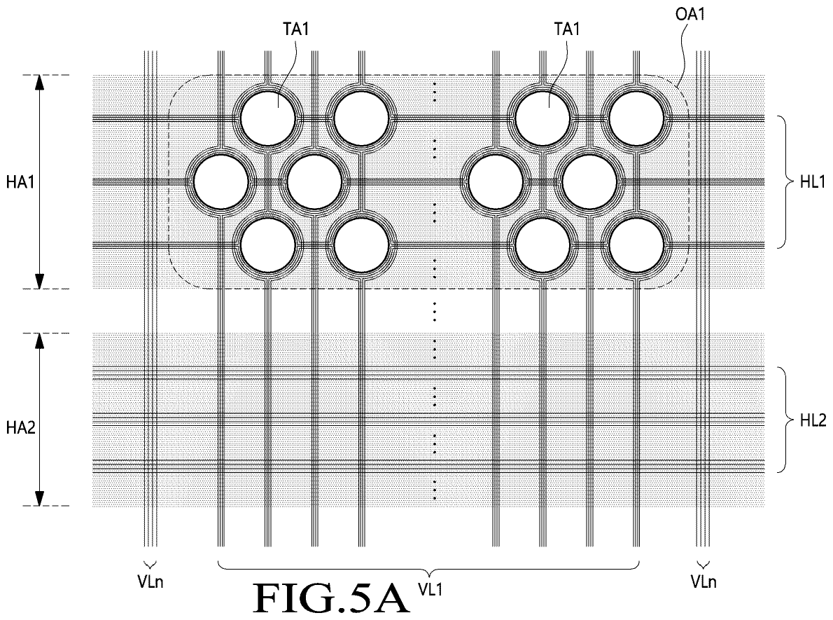

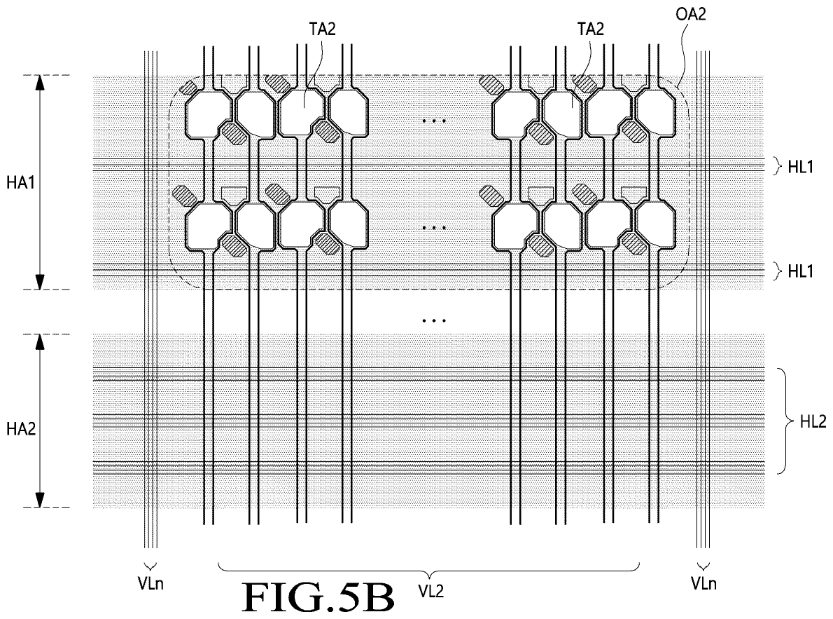

FIGS. 5A and 5B illustrate example arrangements of signal lines disposed in the display panel 110 according to aspects of the present disclosure.

FIG. 5A illustrates example arrangements of signal lines in each of the first optical area OA1 and the normal area NA. FIG. 5B illustrates example arrangements of signal lines in each of the second optical area OA2 and the normal area NA.

First horizontal display areas HA1 shown in FIGS. 5A and 5B are portions of the first horizontal display area HA1 of the display panel 110. Second horizontal display areas HA2 shown in FIGS. 5A and 5B are portions of the second horizontal display area HA2 of the display panel 110.

A first optical area OA1 shown in FIG. 5A is a portion of the first optical area OA1 of the display panel 110, and a second optical area OA2 shown in FIG. 5B is a portion of the second optical area OA2 of the display panel 110.

Referring to FIGS. 5A and 5B, in one or more example embodiments, the first horizontal display area HA1 can include a portion of the normal area NA, the first optical area OA1, and the second optical area OA2. The second horizontal display area HA2 can include only the normal area NA.

Several types of horizontal lines (HL1 and HL2) and several types of vertical lines (VLn, VL1, and VL2) can be disposed in the display panel 110.

Herein, the term “horizontal” and the term “vertical” are used to refer to two directions intersecting in the display panel, but it should be noted that the horizontal direction and the vertical direction can be interchanged depending on a direction in which the display panel 110 or the display device 110 is viewed. The horizontal direction can refer to, for example, a direction in which one gate line GL extends and, and the vertical direction can refer to, for example, a direction in which one data line DL extends. As such, the term horizontal and the term vertical are used to represent two directions.

Referring to FIGS. 5A and 5B, the horizontal lines disposed in the display panel 110 can include first horizontal lines HL1 disposed in the first horizontal display area HA1 and second horizontal lines HL2 disposed on the second horizontal display area HA2.

The horizontal lines disposed in the display panel 110 can be gate lines GL. For example, the first horizontal lines HL1 and the second horizontal lines HL2 can be gate lines GL. The gate lines GL can include several types of gate lines according to structures of one or more subpixels SP.

Referring to FIGS. 5A and 5B, the vertical lines disposed in the display panel 110 can include normal vertical lines VLn disposed only in the normal area NA, first vertical lines VL1 running through both of the first optical area OA1 and the normal area NA, and second vertical lines VL2 running through both of the second optical area OA2 and the normal area NA.

The vertical lines disposed in the display panel 110 can include data lines DL, driving voltage lines DVL, and the like, and can further include reference voltage lines, initialization voltage lines, and the like. For example, the normal vertical lines VLn, the first vertical lines VL1 and the second vertical lines VL2 can include data lines DL, driving voltage lines DVL, and the like, and further include reference voltage lines, initialization voltage lines, and the like.

Herein, it should be noted that the term “horizontal” in the second horizontal line HL2 can mean only that a signal is carried from a left side to a right side, of the display panel (or from the right side to the left side), and may not mean that the second horizontal line HL2 runs in a straight line only in the direct horizontal direction. For example, in FIGS. 5A and 5B, although the second horizontal lines HL2 are illustrated in a straight line, one or more of the second horizontal lines HL2 can include one or more bent or folded portions that are different from the configurations shown in FIGS. 5A and 5B. Likewise, one or more of the first horizontal lines HL1 can also include one or more bent or folded portions.

Herein, it should be noted that the term “vertical” in the normal vertical line VLn can mean only that a signal is carried from an upper portion to a lower portion of the display panel (or from the lower portion to the upper portion), and may not mean that the normal vertical line VLn runs in a straight line only in the direct vertical direction. For example, in FIGS. 5A and 5B, although the normal vertical lines VLn are illustrated in a straight line, one or more of the normal vertical lines VLn can include one or more bent or folded portions that are different from the configurations shown in FIGS. 5A and 5B. Likewise, one or more of the first vertical line VL1 and one or more of the second vertical line VL2 can also include one or more bent or folded portions.

Referring to FIG. 5A, the first optical area OA1 included in the first horizontal area HA1 can include a plurality of light emitting areas EA, and a plurality of first transmissive areas TA1. In the first optical area OA1, an area outside of the plurality of first transmissive areas TA1 can include the plurality of light emitting areas EA.

Referring to FIG. 5A, to improve the transmittance of the first optical area OA1, first horizontal lines HL1 can run through the first optical area OA1 while avoiding the plurality of first transmissive areas TA1 in the first optical area OA1.

According to this configuration, each of the first horizontal lines HL1 running through the first optical area OA1 can include one or more curved or bent portions running around one or more respective outer edges of one or more of the plurality of first transmissive areas TA1 in the first optical area OA1.

Accordingly, one or more first horizontal lines HL1 disposed in the first horizontal area HA1 and one or more second horizontal lines HL2 disposed in the second horizontal area HA2 can have different shapes or lengths. For example, one or more first horizontal lines HL1 running through the first optical area OA1 and one or more second horizontal lines HL2 not running through the first optical area OA1 can have different shapes or lengths.

Further, to improve the transmittance of the first optical area OA1, first vertical lines VL1 can run through the first optical area OA1 while avoiding the plurality of first transmissive areas TA1 in the first optical area OA1.

According to this configuration, each of the first vertical lines VL1 running through the first optical area OA1 can include one or more curved or bent portions running around one or more respective outer edges of one or more of the plurality of first transmissive areas TA1 in the first optical area OA1.

For example, one or more first vertical lines VL1 running through the first optical area OA1 and one or more normal vertical lines VLn disposed in the normal area NA without running through the first optical area OA1 can have different shapes or lengths.

Referring to FIG. 5A, the first transmissive areas TA1 included in the first optical area OA1 in the first horizontal area HA1 can be arranged in a diagonal direction.

Referring to FIG. 5A, in the first optical area OA1 in the first horizontal area HA1, one or more light emitting areas EA can be disposed between two horizontally adjacent first transmissive areas TA1. In the first optical area OA1 in the first horizontal area HA1, one or more light emitting areas EA can be disposed between two vertically adjacent first transmissive areas TA1.

Referring to FIG. 5A, each of the first horizontal lines HL1 disposed in the first horizontal area HA1 (e.g., each of the first horizontal lines HL1 running through the first optical area OA1) can include one or more curved or bent portions running around one or more respective outer edges of one or more of the first transmissive areas TA1.

Referring to FIG. 5B, the second optical area OA2 included in the first horizontal area HA1 can include a plurality of light emitting areas EA, and a plurality of second transmissive areas TA2. In the second optical area OA2, an area outside of the plurality of second transmissive areas TA2 can include the plurality of light emitting areas EA.

In one or more aspects, the plurality of light emitting areas EA and the plurality of second transmissive areas TA2 in the second optical area OA2 can have substantially the same locations and arrangements as the plurality of light emitting areas EA and the plurality of first transmissive areas TA1 in the first optical area OA1 of FIG. 5A.

In one or more aspects, as shown in FIG. 5B, the plurality of light emitting areas EA and the plurality of second transmissive areas TA2 in the second optical area OA2 can have locations and arrangements different from the plurality of light emitting areas EA and the plurality of first transmissive areas TA1 in the first optical area OA1 of FIG. 5A.

For example, referring to FIG. 5B, the plurality of second transmissive areas TA2 in the second optical area OA2 can be arranged in the horizontal direction. In this example, a light emitting area EA may not be disposed between two horizontally adjacent second transmissive areas TA2. Further, one or more of the plurality of light emitting areas EA in the second optical area OA2 can be disposed between vertically adjacent second transmissive areas TA2. For example, one or more light emitting areas EA can be disposed between two rows of second transmissive areas.

In one or more aspects, when the first horizontal lines HL1 run through the second optical area OA2 and the normal area NA adjacent to the second optical area OA2 in the first horizontal area HA1, the first horizontal lines HL1 can have substantially the same arrangement as the first horizontal lines HL1 of FIG. 5A.

In one or more aspects, as shown in FIG. 5B, when the first horizontal lines HL1 run through the second optical area OA2 and the normal area NA adjacent to the second optical area OA2 in the first horizontal area HA1, the first horizontal lines HL1 can have an arrangement different from the first horizontal lines HL1 of FIG. 5A.

This is because the light emitting areas EA and the second transmissive areas TA2 in the second optical area OA2 of FIG. 5B have locations and arrangements different from the light emitting areas EA and the first transmissive areas TA1 in the first optical area OA1 of FIG. 5A.

Referring to FIG. 5B, when the first horizontal lines HL1 run through the second optical area OA2 and the normal area NA adjacent to the second optical area OA2 in the first horizontal area HA1, the first horizontal lines HL1 can run between vertically adjacent second transmissive areas TA2 in a straight line without having a curved or bent portion.

For example, one first horizontal line HL1 can have one or more curved or bent portions in the first optical area OA1, but may not have a curved or bent portion in the second optical area OA2.

To improve the transmittance of the second optical area OA2, the second vertical lines VL2 can run through the second optical area OA2 while avoiding the second transmissive areas TA2 in the second optical area OA2.

According to this configuration, each of the second vertical lines VL2 running through the second optical area OA2 can include one or more curved or bent portions running around one or more respective outer edges of one or more of the second transmissive areas TA2.

For example, one or more second vertical lines VL2 running through the second optical area OA2 and one or more normal vertical lines VLn disposed in the normal area NA without running through the second optical area OA2 can have different shapes or lengths.

As shown in FIG. 5A, each, or one or more, of the first horizontal lines HL1 running through the first optical area OA1 can have one or more curved or bent portions running around one or more respective outer edges of one or more of the first transmissive areas TA1.

Accordingly, a length of first horizontal lines HL1 running through the first optical area OA1 and the second optical area OA2 can be slightly longer than a length of second horizontal lines HL2 disposed only in the normal area NA without running through the first optical area OA1 and the second optical area OA2.

Accordingly, a resistance of first horizontal lines HL1 running through the first optical area OA1 and the second optical area OA2, which is referred to as a first resistance, can be slightly greater than a resistance of second horizontal lines HL2 disposed only in the normal area NA without running through the first optical area OA1 and the second optical area OA2, which is referred to as a second resistance.

Referring to FIGS. 5A and 5B, according to a light transmissive structure, since the first optical area OA1 at least partially overlapping with the first optical electronic device 11 includes a plurality of first transmissive areas TA1, and the second optical area OA2 at least partially overlapping with the second optical electronic device 12 includes a plurality of second transmissive areas TA2, therefore, the first optical area OA1 and the second optical area OA2 can have the number of subpixels per unit area less than the normal area NA.

Accordingly, the number of subpixels connected to each, or one or more, of the first horizontal lines HL1 running through the first optical area OA1 and the second optical area OA2 can be different from the number of subpixels connected to each, or one or more, of the second horizontal lines HL2 disposed only in the normal area NA without running through the first optical area OA1 and the second optical area OA2.

The number of subpixels connected to each, or one or more, of the first horizontal lines HL1 running through the first optical area OA1 and the second optical area OA2, which is referred to as a first number, can be less than the number of subpixels connected to each, or one or more, of the second horizontal lines HL2 disposed only in the normal area NA without running through the first optical area OA1 and the second optical area OA2, which is referred to as a second number.

A difference between the first number and the second number can vary depending on a difference between a resolution of each of the first optical area OA1 and the second optical area OA2 and a resolution of the normal area NA. For example, as a difference between a resolution of each of the first optical area OA1 and the second optical area OA2 and a resolution of the normal area NA increases, a difference between the first number and the second number can increase.

As described above, since the number (the first number) of subpixels connected to each, or one or more, of the first horizontal lines HL1 running through the first optical area OA1 and the second optical area OA2 is less than the number of subpixels (the second number) connected to each, or one or more, of the second horizontal lines HL2 disposed only in the normal area NA without running through the first optical area OA1 and the second optical area OA2, an area where the first horizontal line HL1 overlaps with one or more other electrodes or lines adjacent to the first horizontal line HL1 can be smaller than an area where the second horizontal line HL2 overlaps with one or more other electrodes or lines adjacent to the second horizontal line HL2.

Accordingly, a parasitic capacitance formed between the first horizontal line HL1 and one or more other electrodes or lines adjacent to the first horizontal line HL1, which is referred to as a first capacitance, can be greatly less than a parasitic capacitance formed between the second horizontal line HL2 and one or more other electrodes or lines adjacent to the second horizontal line HL2, which is referred to as a second capacitance.

Considering a relationship in magnitude between the first resistance and the second resistance (e.g., the first resistance≥the second resistance) and a relationship in magnitude between the first capacitance and the second capacitance (e.g., the first capacitance<<second capacitance), a resistance-capacitance (RC) value of the first horizontal line HL1 running through the first optical area OA1 and the second optical area OA2, which is referred to as a first RC value, can be greatly less than an RC value of the second horizontal lines HL2 disposed only in the normal area NA without running through the first optical area OA1 and the second optical area OA2, which is referred to as a second RC value. Thus, in this example, the first RC value is greatly less than the second RC value (e.g., the first RC value<<the second RC value).

Due to such a difference between the first RC value of the first horizontal line HL1 and the second RC value of the second horizontal line HL2, which is referred to as an RC load difference, a signal transmission characteristic through the first horizontal line HL1 can be different from a signal transmission characteristic through the second horizontal line HL2.

Hereinafter, for convenience of explanation, at least one of the first optical area OA1 and the second optical area OA2 can be described as an optical area OA, and at least one of the plurality of first transmissive areas TA1 in the first optical area OA1 and the plurality of second transmissive areas TA2 in the second optical area OA2 can be described as a transmissive area TA.

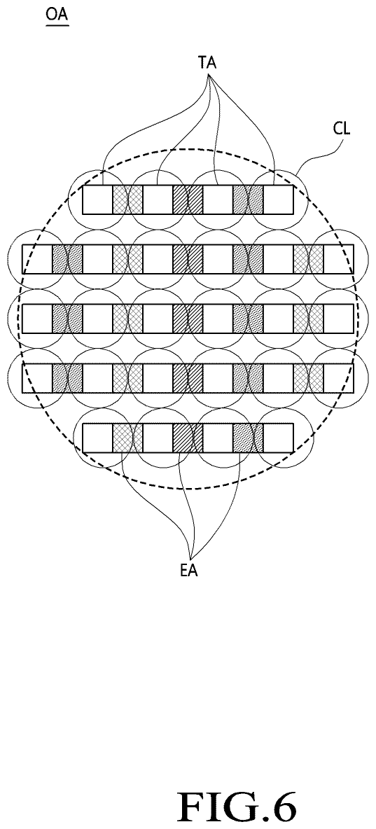

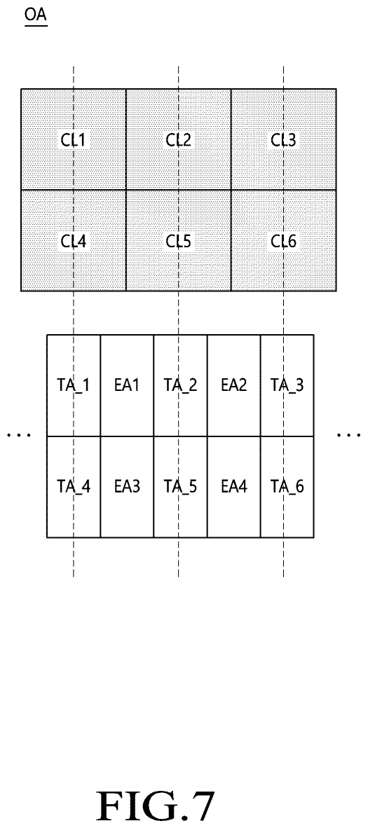

FIGS. 6 and 7 illustrate example configurations of an optical area in the display panel 110 according to aspects of the present disclosure.

FIG. 6 is a plan view illustrating an example arrangement of lenses disposed in an optical area OA (e.g., the first optical area OA1 or the second optical area OA1 discussed above) according to aspects of the present disclosure. FIG. 7 is a more detailed plan view illustrating an example arrangement of lenses disposed in the optical area OA according to aspects of the present disclosure.

Referring to FIGS. 6 and 7, in one or more example embodiments, the optical area OA can include a plurality of transmissive areas TA and a plurality of light emitting areas EA, and overlap with at least one of optical electronic devices (e.g., the first optical electronic device 11 and the second optical electronic device 12 discussed above) disposed under, or at a lower portion of, the display panel 110.

For example, when the optical area OA is the first optical area OA1, the optical area OA can overlap with the first optical electronic device 11. Further, when the optical area OA is the second optical area OA2, the optical area OA can overlap with the second optical electronic device 12.

For example, the plurality of light emitting areas EA can include at least one red subpixel, at least one green subpixel, and at least one blue subpixel, but aspects of the present disclosure are not limited thereto. For example, the plurality of light emitting areas EA can include at least one subpixel among the red subpixel, the green subpixel, and the blue subpixel, or can further include one or more subpixels of one or more colors other than the red subpixel, the green subpixel, and the blue subpixel.

The optical area OA can include a plurality of lenses CL overlapping with the plurality of transmissive areas TA, respectively. The plurality of lenses CL can be, for example, light-collecting lenses capable of focusing external light incident on at least one of the optical electronic devices (11 and 12) overlapping with the optical area OA onto the plurality of transmissive areas TA, respectively.

In one or more aspects, the plurality of lenses CL in the examples of FIGS. 6 and 7 can have a circular or rectangular shape in the plan view, but aspects of the present disclosure are not limited thereto. For example, the plurality of lenses CL can have a polygonal shape other than the circular or rectangular shape.

In one or more aspects, the optical area OA can include a plurality of transmissive areas TA to enable the optical electronic device (11 or 12) disposed under, or at a lower portion of, the display panel 110 to receive external light. In this configuration, the plurality of transmissive areas TA can be expanded to improve the performance of the optical electronic device (11 or 12).

However, when the plurality of transmissive areas TA are expanded, the display quality of images presented by light emitting areas EA in the optical area OA may be degraded. For example, image artifacts such as a blur phenomenon of the display image and the like may occur due to the arrangement of the plurality of light emitting areas EA and the plurality of transmissive areas TA in a grid configuration on the optical electronic device (11 or 12), and the operation performance of the optical electronic device (11 or 12) may be degraded.

To address this issue, in one or more aspects, the display device 100 can include a structure where the plurality of lenses CL are disposed to respectively overlap with the plurality of transmissive areas TA on the plurality of transmissive areas TA in the optical area OA, and thereby, can provide advantages of curing or preventing the degradation of display quality, the image artifacts such as the blur phenomenon, the degradation of the operation performance of the optical electronic device (11 or 12), and the like.

The number of lenses CL can be, for example, the same as the number of transmissive areas TA. For example, the plurality of lenses CL can be disposed on the plurality of transmissive areas TA by being matched to the plurality of transmissive areas TA on a one-to-one basis. Therefore, the efficiency of focusing external light onto the plurality of transmissive areas TA can be maximized through the plurality of lenses CL. Also, each of the plurality of lenses CL can be larger than each of the plurality of transmissive areas TA, but embodiments are not limited thereto.

For example, the display device 100 can maximize the efficiency of directing external light to transmissive areas TA while minimizing or preventing the traveling of external light to light emitting areas EA by optimizing the arrangement of the plurality of lenses CL in the optical area OA.

For example, the plurality of lenses CL can be refractive lenses having a predetermined refractive index.

For example, when the plurality of lenses CL are refractive lenses, the refractive index can be 1.5 to 1.8 (e.g., 1.65), but aspects of the present disclosure are not limited thereto. For example, the plurality of lenses CL can be designed to have a refractive index of 1.8 or higher, or a refractive index of 1.5 or lower.

Referring to FIG. 7, in one or more example embodiments, the optical area OA can include first to sixth transmissive areas (TA_1, TA_2, TA_3, TA_4, TA_5, and TA_6) and first to fourth light emitting areas (EA1, EA2, EA3, and EA4) disposed between the first to sixth transmissive areas (TA_1, TA_2, TA_3, TA_4, TA_5, and TA_6).

It should be noted that although FIG. 7 illustrates 6 transmissive areas TA and 4 light emitting areas EA disposed in the optical area OA for convenience of explanation, however, aspects of the present disclosure are not limited thereto. For example, the optical area OA can include 6 or more transmissive areas TA and 4 or more light emitting areas EA.

Referring to FIG. 7, the first to fourth light emitting areas (EA1, EA2, EA3, and EA4) can be disposed as follows: the first light emitting area EA1 can be disposed between the first transmissive area TA_1 and the second transmissive area TA_2; the second light emitting area EA2 can be disposed between the second transmissive area TA_2 and the third light emitting area TA_3; the third light emitting area EA3 can be disposed between the fourth transmissive area TA_4 and the fifth light emitting area TA_5; and the fourth light emitting area EA4 can be disposed between the fifth transmissive area TA_5 and the sixth light emitting area TA_6.

The optical area OA can include first to sixth lenses (CL1, CL2, CL3, CL4, CL5, and CL6) overlapping with the first to sixth transmissive areas (TA_1, TA_2, TA_3, TA_4, TA_5, and TA_6), respectively. According to an embodiment, centers of the first to sixth lenses can be aligned with and overlap centers of the first to sixth transmissive areas, but embodiments are not limited thereto.

For example, the first lens CL1 can overlap with the first transmissive area TA_1, the second lens CL2 can overlap with the second transmissive area TA_2, and the third lens CL3 can overlap with the third transmissive area TA_3.

Further, the fourth lens CL4 can overlap with the fourth transmissive area TA_4, the fifth lens CL5 can overlap with the fifth transmissive area TA_5, and the sixth lens CL6 can overlap with the sixth transmissive area TA_6.

Referring to FIG. 7, a respective central axis of each of the first to sixth lenses (CL1, CL2, CL3, CL4, CL5, and CL6) can be disposed to be aligned with one or more central axes of the first to sixth transmissive areas (TA_1, TA_2, TA_3, TA_4, TA_5, and TA_6), but aspects of the present disclosure are not limited thereto.

Each of the first to fourth light emitting areas (EA1, EA2, EA3, and EA4) can overlap with at least two or more lenses.

For example, the first light emitting area EA1 can be disposed such that at least a portion of the first lens CL1 overlaps with a first area of the first light emitting area EA1, and at least a portion of the second lens CL2 overlaps with a second area of the first light emitting area EA1 having the same area as the first area of the first light emitting area EA1.

The second light emitting area EA2 can be disposed such that at least a portion of the second lens CL2 overlaps with a first area of the second light emitting area EA2, and at least a portion of the third lens CL3 overlaps with a second area of the second light emitting area EA2 having the same area as the first area of the second light emitting area EA2.

The third light emitting area EA3 can be disposed such that at least a portion of the fourth lens CL4 overlaps with a first area of the third light emitting area EA3, and at least a portion of the fifth lens CL5 overlaps with a second area of the third light emitting area EA3 having the same area as the first area of the third light emitting area EA3.

The fourth light emitting area EA4 can be disposed such that at least a portion of the fifth lens CL5 overlaps with a first area of the fourth light emitting area EA4, and at least a portion of the sixth lens CL6 overlaps with a second area of the fourth light emitting area EA4 having the same area as the first area of the fourth light emitting area EA4.

For example, when a respective length of each of the first to fourth light emitting areas (EA1, EA2, EA3, and EA4) in a direction in which the first to third transmissive areas (TA_1, TA_2, and TA_3) are disposed is ‘l’, a respective length of each of the first area and the second area can be ‘l/2’, but aspects of the present disclosure are not limited thereto.

For example, each of the first to sixth lenses (CL1, CL2, CL3, CL4, CL5, and CL6) can be designed to have an area overlapping with one whole transmissive area and at least respective portions of two light emitting areas adjacent to one transmissive area.

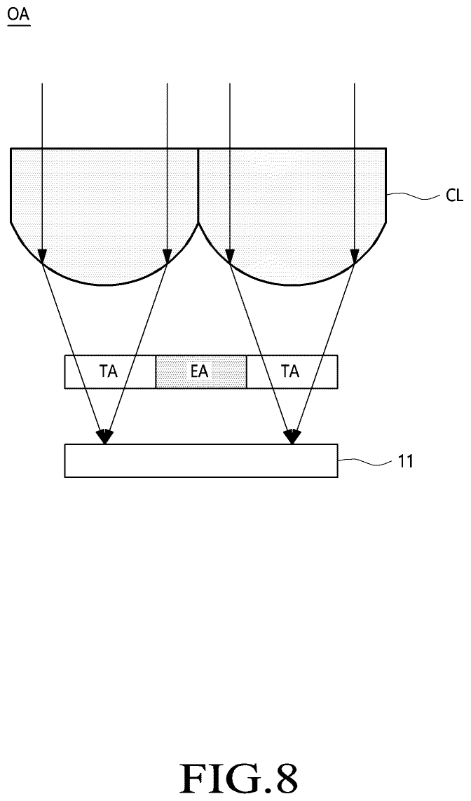

FIG. 8 illustrates example lenses disposed in an optical area OA (e.g., the first optical area OA1 or the second optical area OA2 discussed above), which are implemented using refracting lenses, according to aspects of the present disclosure.

Referring to FIG. 8, in one or more example embodiments, the display device 100 can include a plurality of lenses CL disposed on a plurality of transmissive areas TA and overlapping with the plurality of transmissive areas TA on a one-to-one basis in the optical area OA including the plurality of transmissive areas TA and a plurality of light emitting areas EA overlapping with the first optical electronic device 11.

It should be noted that for convenience of explanation, although FIG. 8 illustrates an example in which the optical area OA is the first optical area OA1, and the plurality of transmissive areas TA and the plurality of light emitting areas EA overlap with the first optical electronic device 11, however, aspects of the present disclosure are not limited thereto. For example, when the optical area OA of FIG. 8 is the second optical area OA2, the plurality of transmissive areas TA and the plurality of light emitting areas EA can overlap with the second optical electronic device 12.

The plurality of lenses CL can be refractive lenses having a predetermined refractive index. In this implementation, the plurality of lenses CL can focus external light incident toward the first optical electronic device 11 onto the plurality of transmissive areas TA, respectively. According to an embodiment, an interface between two adjacent lenses CL can overlap with a center of a light emitting area EA, but embodiments are not limited thereto.

The plurality of lenses CL can also serve to diffuse light output from the plurality of light emitting areas EA, respectively.

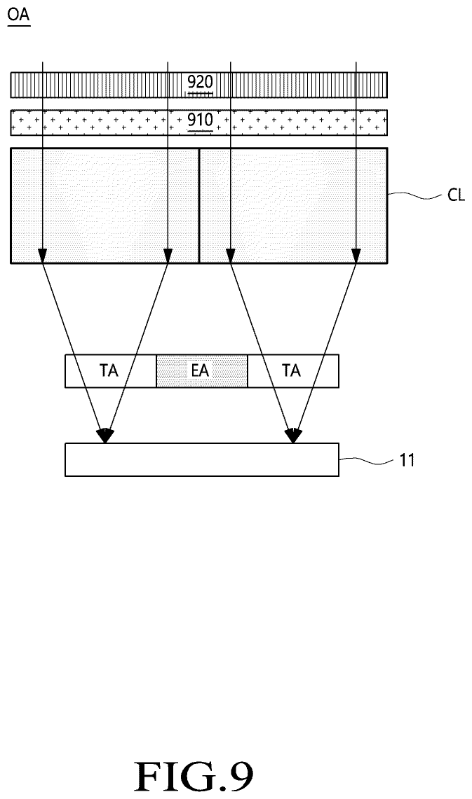

FIG. 9 illustrates example lenses disposed in an optical area OA (e.g., the first optical area OA1 or the second optical area OA2 discussed above), which are implemented using polarizing lenses, according to aspects of the present disclosure.

Referring to FIG. 9, in one or more example embodiments, the display device 100 can include a plurality of lenses CL disposed on a plurality of transmissive areas TA and overlapping with the plurality of transmissive areas TA on a one-to-one basis in the optical area OA including the plurality of transmissive areas TA and a plurality of light emitting areas EA overlapping with the first optical electronic device 11.

It should be noted that for convenience of explanation, although FIG. 9 illustrates an example in which the optical area OA is the first optical area OA1, and the plurality of transmissive areas TA and the plurality of light emitting areas EA overlap with the first optical electronic device 11, however, aspects of the present disclosure are not limited thereto. For example, when the optical area OA of FIG. 9 is the second optical area OA2, the plurality of transmissive areas TA and the plurality of light emitting areas EA can overlap with the second optical electronic device 12.

For example, the plurality of lenses CL can be polarizing lenses (e.g., liquid crystal polarizing lenses) capable of converting first circularly polarized light (external light) into second circularly polarized light and focusing the second circularly polarized light onto the plurality of transmissive areas TA, respectively. The plurality of lenses CL can be Pancharatnam-Berry optical lenses, or be lenses operating in a similar manner thereto, but aspects of the present disclosure are not limited thereto.

For example, the first circularly polarized light can be right-circularly polarized light, and the second circularly polarized light can be left-circularly polarized light.

The display device 100 can further include a first polarizing plate 910 disposed on the plurality of lenses and a second polarizing plate 920 disposed on the first polarizing plate 910, in the example where the plurality of lenses CL are polarizing lenses. The first polarizing plate 910 and the second polarizing plate 920 can overlap with both the optical area OA and the normal area NA.

For example, the first polarizing plate 910 can be a circular polarizing plate, and the second polarizing plate 920 can be a linear polarizing plate. For example, the first polarizing plate 910 can be a λ/4 phase retardation film (e.g., quarter wave plate (QWP)), but aspects of the present disclosure are not limited thereto.

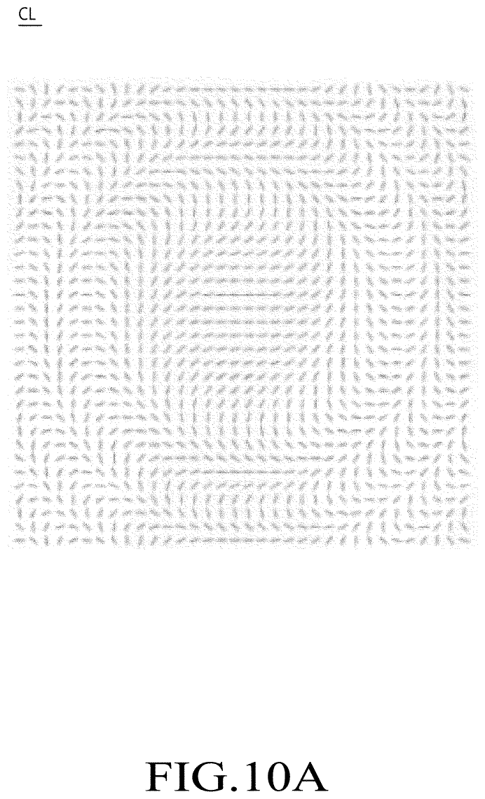

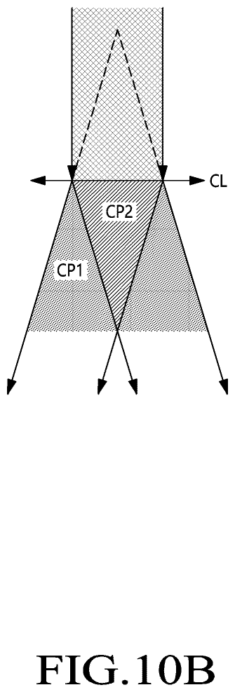

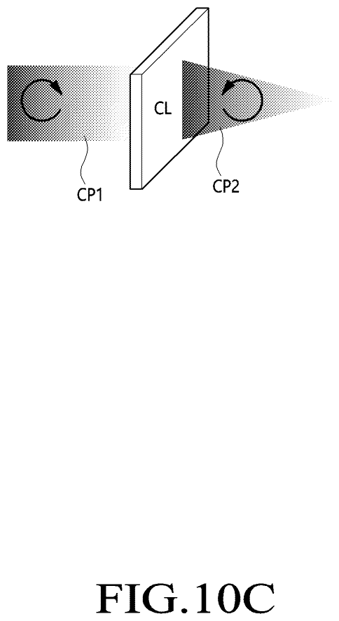

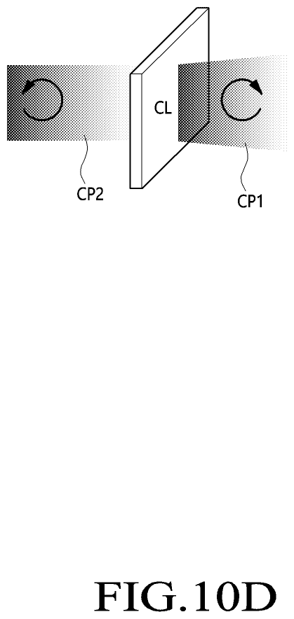

FIGS. 10A to 10D illustrate example configurations of a plurality of lenses disposed in an optical area OA (e.g., the first optical area OA1 or the second optical area OA2 discussed above), which are implemented using polarizing lenses, according to aspects of the present disclosure.

FIG. 10A illustrates an example where lenses CL are implemented using liquid crystal polarizing lenses. FIG. 10B illustrates optical characteristics of the liquid crystal polarizing lens. FIG. 10C illustrates a light-collecting characteristic among optical characteristics of the liquid crystal polarizing lens. FIG. 10D illustrates a diffusion characteristic among optical characteristics of the liquid crystal polarizing lens.

Referring to FIG. 10A, in one or more example embodiments, the display device 100 can include a plurality of lenses CL disposed on a plurality of transmissive areas TA in the optical area OA and overlapping with the plurality of transmissive areas TA on a one-to one basis, and the plurality of lenses CL can be, for example, liquid crystal polarizing lenses.

In one or more aspects, the plurality of lenses CL implemented using liquid crystal polarizing lenses can control an arrangement of a plurality of liquid crystals according to electric field applied from the outside. For example, the plurality of lenses CL can convert first circularly polarized light (e.g., right-circularly polarized light) into second circularly polarized light (e.g., left-circularly polarized light) or converting the second circularly polarized light into first circularly polarized light.

Referring to FIGS. 10B and 10C, the plurality of lenses CL implemented using the liquid crystal polarizing lenses can convert first circularly polarized light CL1 into second circularly polarized light CL2, and at the same time, can focus the second circularly polarized light CL2. For example, each of the plurality of lenses CL can perform two operations, such as making the light spin in the opposite direction and bending the light to meet at a single point (e.g., a focal point).

Referring to FIGS. 10B and 10D, the plurality of lenses CL implemented using the liquid crystal polarizing lenses can convert second circularly polarized light CL2 into first circularly polarized light CL1, and at the same time, can diffuse the first circularly polarized light CL1. For example, each of the plurality of lenses CL can perform two operations, such as making the light spin in the opposite direction and diffusing the light so that the light spreads out rather than being concentrated or focusing it.

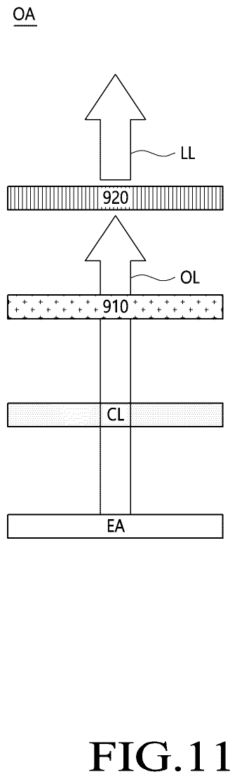

FIG. 11 illustrates an example light-outputting characteristic of a plurality of lenses disposed in an optical area OA (e.g., the first optical area OA1 or the second optical area OA2 discussed above), which are implemented using polarizing lenses, according to aspects of the present disclosure.

Referring to FIG. 11, in one or more example embodiments, in the display device 100, light OL output from a light emitting area EA in the optical area OA can be directed to a second polarizing plate 920.

For example, the light OL output from the light emitting area EA can be randomly vibrating light (e.g., light in a randomly polarized state).

For example, the light OL output from the light emitting area EA can passes through a lens CL and a first polarizing plate 910, and then, enter the linear polarizing plate 920. In this situation, the lens CL and the first polarizing plate 910 may not affect the polarization state of the light OL output from the light emitting area EA.

In contrast, the second polarizing plate 920 can convert the light OL from the light emitting area EA into linearly polarized light LL. For example, the linearly polarized light LL can have an electric field that oscillates in a single, fixed plane perpendicular to the direction the light is traveling.

The first polarizing plate 910 and the second polarizing plate 920 can be disposed to overlap with not only the optical area OA but also the normal area NA. According to this configuration, the second polarizing plate 920 can also convert light OL emitted from light emitting areas EA disposed in the normal area NA into linearly polarized light LL.

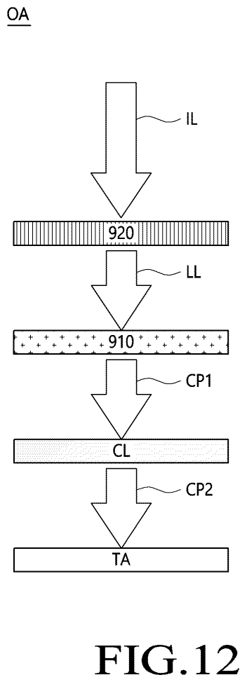

FIG. 12 illustrates an example light-receiving characteristic of a plurality of lenses disposed in an optical area OA (e.g., the first optical area OA1 or the second optical area OA2 discussed above), which are implemented using polarizing lenses, according to aspects of the present disclosure.

Referring to FIG. 12, in one or more example embodiments, the display device 100 can control a polarization state of external light incident on an optical electronic device (e.g., the first optical electronic device 11 or the second optical electronic device and 12) through a second polarizing plate 920, a first polarizing plate 910, and a lens CL, and at the same time, focus the external light whose polarization state is controlled onto a transmissive area TA.

The second polarizing plate 920 can convert the external light IL into linearly polarized light LL, and the first polarizing plate 910 can convert the linearly polarized light LL into first circularly polarized light CP1.

The lens CL can convert the first circularly polarized light CP1 into second circularly polarized light CP2, and at the same time, focus the second circularly polarized light CP2 onto the transmissive area TA.

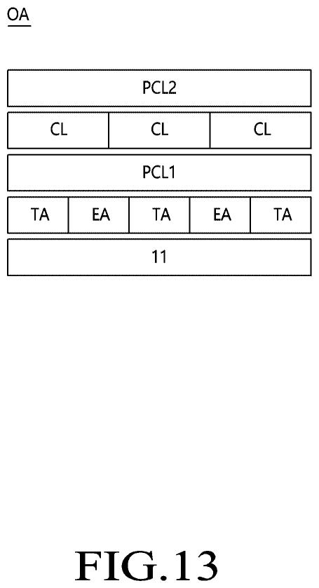

FIG. 13 illustrates an example formation of an optical area OA (e.g., the first optical area OA1 or the second optical area OA2 discussed above) according to aspects of the present disclosure.

Referring to FIG. 13, in one or more example embodiments, the display device 100 can include the optical area OA including a plurality of light emitting areas EA and a plurality of transmissive areas TA overlapping with the first optical electronic device 11, and a first encapsulation layer PCL1, a plurality of lenses CL, and a second encapsulation layer PCL2, which overlap with the optical area OA.

It should be noted that for convenience of explanation, although FIG. 13 illustrates an example where the optical area OA is the first optical area OA1, and the plurality of transmissive areas TA and the plurality of light emitting areas EA overlap with the first optical electronic device 11, however, aspects of the present disclosure are not limited thereto. For example, in an example where the optical area OA of FIG. 13 is the second optical area OA2, the plurality of transmissive areas TA and the plurality of light emitting areas EA can overlap with the second optical electronic device 12.

For example, the first encapsulation layer PCL1 can be disposed on the plurality of light emitting areas EA and the plurality of transmissive areas TA, the plurality of lenses CL can be disposed on the first encapsulation layer PCL1, and the second encapsulation layer PCL2 can be disposed on the plurality of lenses CL.

For example, an adhesive layer can be disposed between the first encapsulation layer PCL1 and the plurality of lenses CL. Thereby, an adhesive strength between the first encapsulation layer PCL1 and the plurality of lenses CL can be improved.

In one or more aspects, the display device 100 can further include a substrate and a planarization layer disposed on the substrate. In this configuration, a plurality of light emitting areas EA located in each of the optical area OA and the normal area NA and a plurality of transmissive areas TA located in the optical area OA can be disposed on the planarization layer.

For example, a plurality of first light emitting elements corresponding to the plurality of light emitting areas EA located in the optical area OA, and a plurality of second light emitting elements corresponding to the plurality of light emitting areas EA located in the normal area NA can be disposed on the planarization layer.

For example, the plurality of first light emitting elements in the optical area OA and the plurality of second light emitting elements in the normal area NA can be formed in the same layer. However, according to another embodiment, the plurality of first light emitting elements in the optical area OA and the plurality of second light emitting elements in the normal area NA can be formed on different layers.

In one or more aspects, the display device 100 can further include a cover glass disposed on the second encapsulating layer PCL2. In this configuration, an adhesive layer can be disposed between the second encapsulating layer PCL2 and the cover glass, and thereby, an adhesive strength between the second encapsulating layer PCL2 and the cover glass can be improved.

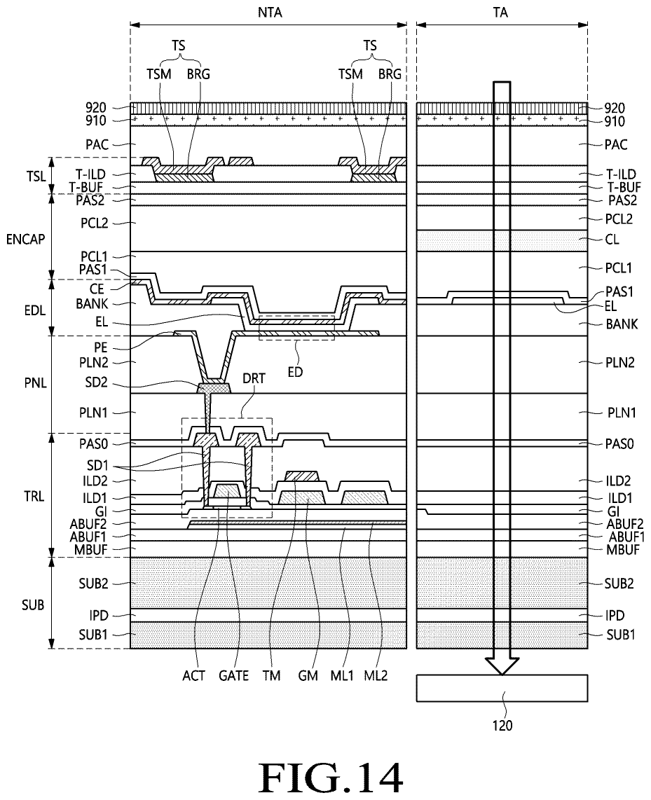

FIG. 14 illustrates an example stack-up structure of the display device 100 according to aspects of the present disclosure.

Referring to FIG. 14, in one or more example embodiments, the display device 100 can include a non-transmissive area NTA and at least one transmissive area TA in an optical area OA (e.g., the first optical area OA1 or the second optical area OA2 discussed above).

The non-transmissive area NTA can be included in both the optical area OA and the normal area NA, and the non-transmissive area NTA included in the optical area OA and the normal area NA can include a plurality of light emitting areas EA of each of the optical area OA and the normal area NA.

Although FIG. 14 illustrates an example where the transmissive area TA of the optical area OA overlaps with the first optical electronic device 11 for convenience of explanation, however, aspects of the present disclosure are not limited thereto. For example, the transmissive area TA of the optical area OA can also overlap with the second optical electronic device 12.

Further, although FIG. 14 illustrates that the first optical electronic device 11 overlaps with the transmissive area TA of the optical area OA, the optical electronic device 11 can also overlap with a portion of the non-transmissive area NTA included in the optical area OA.

Both the non-transmissive area NTA and the transmissive area TA can include a substrate SUB, a transistor layer TRL, a planarization layer PLN, a light emitting element layer EDL, an encapsulation layer ENCAP, a touch sensor layer TSL, and a protection layer PAC.

Hereinafter, the stack-up structure of the non-transmissive area NTA is described with reference to FIG. 14.

The substrate SUB can include a first substrate SUB1, an interlayer insulating layer IPD, and a second substrate SUB2. The interlayer insulating layer IPD can be located between the first substrate SUB1 and the second substrate SUB2. As the substrate SUB includes the first substrate SUB1, the interlayer insulating layer IPD, and the second substrate SUB2, the penetration of moisture can be effectively prevented. For example, the first substrate SUB1 and the second substrate SUB2 can be polyimide (PI) substrates.

The transistor layer TRL can be disposed with several patterns (e.g., ACT, SD1, GATE), several insulating layers (e.g., MBUF, ABUF1, ABUF2, GI, ILD1, ILD2, PAS0), and several metal patterns (e.g., TM, GM, ML1, ML2) for forming one or more transistors such as a driving transistor DRT.

Hereinafter, the stack-up structure of the transistor layer TRL will be described in more detail.

A multi-buffer layer MBUF can be disposed on the second substrate SUB2, and a first active buffer layer ABUF1 can be disposed on the multi-buffer layer MBUF.

A first metal layer ML1 and a second metal layer ML2 can be disposed on the first active buffer layer ABUF1. For example, each of the first metal layer ML1 and the second metal layer ML2 can serve as a light shield.

A second active buffer layer ABUF2 can be disposed on the first metal layer ML1 and the second metal layer ML2. An active layer ACT of a driving transistor DRT can be disposed on the second active buffer layer ABUF2.

A gate insulating layer GI can be disposed such that it covers the active layer ACT.

A gate electrode GATE of the driving transistor DRT can be disposed on the gate insulating layer GI. In this configuration, at a location different from a location where the driving transistor DRT is disposed, a gate material layer GM can be disposed on the gate insulating layer GI together with the gate electrode GATE of the driving transistor DRT.

A first interlayer insulating layer ILD1 can be disposed such that it covers the gate electrode GATE and the gate material layer GM. A metal pattern TM can be disposed on the first interlayer insulating layer ILD1. A second interlayer insulating layer ILD2 can be disposed such that it covers the metal pattern TM on the first interlayer insulating layer ILD1.

Two first source-drain electrode patterns SD1 can be disposed on the second interlayer insulating layer ILD2. One of the two first source-drain electrode patterns SD1 can be a source node of the driving transistor DRT, and the other thereof can be a drain node of the driving transistor DRT.

The two first source-drain electrode patterns SD1 can be connected to a first side portion and a second opposing side portion of the active layer ACT, respectively, through contact holes of the second interlayer insulating layer ILD2, the first interlayer insulating layer ILD1, and the gate insulating layer GI. A portion of the active layer ACT overlapping with the gate electrode GATE can be defined as a channel region. One of the two first source-drain electrode patterns SD1 can be connected to the first side portion on one side of the channel region of the active layer ACT, and the other of the two first source-drain electrode patterns SD1 can be connected to the second opposing side portion on the other side of the channel region of the active layer ACT.

A passivation layer PAS0 can be disposed such that it covers the two first source-drain electrode patterns SD1.

The planarization layer PLN can be disposed on the transistor layer TRL. The planarization layer PLN can include a first planarization layer PLN1 and a second planarization layer PLN2.

The first planarization layer PLN1 can be disposed on the passivation layer PAS0. A second source-drain electrode pattern SD2 can be disposed on the first planarization layer PLN1. The second source-drain electrode pattern SD2 can be connected to one of the two first source-drain electrode patterns SD1 (which can correspond to the second node N2 of FIG. 3) through a contact hole of the first planarization layer PLN1.

The second planarization layer PLN2 can be disposed such that it covers the second source-drain electrode pattern SD2. The light emitting element layer EDL can be disposed on the second planarization layer PLN2.

The light emitting element layer EDL can include a light emitting element ED formed by a pixel electrode PE, an emission layer EL, and a common electrode CE. The emission layer EL can include an organic layer.

For example, the light emitting element ED of FIG. 14 can be a first light emitting element in at least one of light emitting areas EA formed in the optical area OA, or a second light emitting element in at least one of light emitting areas EA formed in the normal area NA.

The pixel electrode PE can be disposed on the second planarization layer PLN2, and the pixel electrode PE can be electrically connected to the second source-drain electrode pattern SD2 through a contact hole of the second planarization layer PLN2.

A bank BANK can be disposed such that it covers the pixel electrode PE. The bank BANK can have an opening where a portion corresponding to the light emitting area of a corresponding subpixel SP is opened. A portion of the pixel electrode PE can be exposed by the opening of the bank BANK. The emission layer EL can be disposed in the opening of the bank BANK and on a peripheral portion surrounding the opening. Accordingly, the emission layer EL can be disposed on the pixel electrode PE exposed through the opening of the bank BANK.

The common electrode CE can be disposed on the emission layer EL. For example, the common electrode CE can be a cathode electrode.

The encapsulation layer ENCAP can be disposed on the light emitting element layer EDL.

The encapsulation layer ENCAP can have a single layer structure or a multi-layer structure. For example, as illustrated in FIG. 14, the encapsulation layer ENCAP can include a lower encapsulation layer PAS1, a first encapsulation layer PCL1, a second encapsulation layer PCL2, and an upper encapsulation layer PAS2.

However, the display device 100 according to aspects of the present disclosure is not limited thereto. For example, the encapsulation layer ENCAP can include only the first encapsulation layer PCL1 and the second encapsulation layer PCL2.

The lower encapsulation layer PAS1 and the upper encapsulation layer PAS2 can be inorganic layers, and the first encapsulation layer PCL1 and the second encapsulation layer PCL2 can be organic layers or inorganic layers. The first encapsulation layer PCL1 and the second encapsulation layer PCL2 can serve as planarization layers.

The lower encapsulation layer PAS1 can be disposed on the common electrode CE and be disposed closest to the light emitting element ED. The lower encapsulation layer PAS1 can include an inorganic insulating material allowing a low-temperature deposition to be performed. For example, the lower encapsulation layer PAS1 can include silicon nitride SiNx), silicon oxide SiOx), silicon oxide nitride SiON), or aluminum oxide Al2O3). Since the lower encapsulation layer PAS1 is deposited in a low-temperature atmosphere, the lower encapsulation layer PAS1 can prevent the emission layer EL, which includes an organic material vulnerable to a high-temperature atmosphere, from being damaged during the deposition process.

The first encapsulation layer PCL1 and the second encapsulation layer PCL2 can include an area smaller than the lower encapsulation layer PAS1. In this configuration, the first encapsulation layer PCL1 and the second encapsulation layer PCL2 can be formed to expose at least one of both ends of the lower encapsulation layer PAS1. The first encapsulation layer PCL1 and the second encapsulation layer PCL2 can serve as a buffer to relieve stress between one or more layers thereunder or thereon when the display device 100 is bent, and can also serve to enhance flattening performance. For example, the first encapsulation layer PCL1 and the second encapsulation layer PCL2 can include an organic insulating material, such as an acrylic resin, an epoxy resin, a polyimide, polyethylene, silicon oxycarbon SiOC, or the like. For example, the first encapsulation layer PCL1 and the second encapsulation layer PCL2 can be formed by an inkjet process.

In one or more aspects, the display panel 110 can include one or more dams disposed at an end of, or in an area adjacent to, an inclined surface of the encapsulation layer ENCAP to prevent the encapsulation layer ENCAP from collapsing or overflowing. The one or more dams can be disposed at, or in an area adjacent to, a boundary of the display area DA and the non-display area NDA.

For example, the first encapsulation layer PCL1 and the second encapsulation layer PCL2 including an organic material can be located only on an inner side of an innermost dam among the one or more dams. For example, the first encapsulation layer PCL1 and the second encapsulation layer PCL2 may not be disposed on all of the one or more dams. In contrast, in an example where first and second dams are disposed, the first encapsulation layer PCL1 and the second encapsulation layer PCL2 including an organic material can be located on the first dam, which is the innermost dam, among the first and second dams. For example, the first encapsulation layer PCL1 and the second encapsulation layer PCL2 can extend only to an upper portion of the first dam. In another example, the first encapsulation layer PCL1 and the second encapsulation layer PCL2 can extend past the upper portion of the first dam to an upper portion of the second dam. Also, a portion of the second encapsulation layer PCL2 overlapping with the lens CL in the transmissive area TA can be thinner than a portion the second encapsulation layer PCL2 in the non-transmissive area NTA. For example, a thickness of the second encapsulation layer PCL2 in the transmissive area TA can be different than a thickness of second encapsulation layer PCL2 in the non-transmissive area NTA.

The upper encapsulation layer PAS2 can be disposed on the substrate SUB on which the first encapsulation layer PCL1 and the second encapsulation layer PCL2 are disposed, and disposed such that the upper encapsulation layer PAS2 covers respective upper surfaces and side surfaces of the first encapsulation layer PCL1, the second encapsulation layer PCL2, and the lower encapsulation layer PAS1. The upper encapsulation layer PAS2 can minimize or block external moisture or oxygen from penetrating into the lower encapsulation layer PAS1, the first encapsulation layer PCL1, and the second encapsulation layer PCL2. For example, the upper encapsulation layer PAS2 can include an inorganic insulating material, such as silicon nitride (SiNx), silicon oxide (SiOx), silicon oxynitride (SiON), aluminum oxide (Al2O3), or the like.

The touch sensor layer TSL can be disposed on the encapsulation layer ENCAP.

A touch buffer layer T-BUF can be disposed on the encapsulation layer ENCAP, and a touch sensor TS can be disposed on the touch buffer layer T-BUF. The touch sensor TS can include touch sensor metals TSM and a bridge metal BRG, which are located in different layers. A touch interlayer insulating layer T-ILD can be disposed between the touch sensor metals TSM and the bridge metal BRG.

For example, the touch sensor metals TSM can include a first touch sensor metal TSM, a second touch sensor metal TSM, and a third touch sensor metal TSM, which are disposed adjacent to each other. The first touch sensor metal TSM and the second touch sensor metal TSM can be electrically connected to each other, and when the third touch sensor metal TSM is located between the first touch sensor metal TSM and the second touch sensor metal TSM, the first touch sensor metal TSM and the second touch sensor metal TSM can be electrically connected through the bridge metal BRG located in a different layer. The bridge metal BRG can be insulated from the third touch sensor metal TSM by the touch interlayer insulating layer T-ILD.

During a process forming the touch sensor layer TSL, a chemical solution (e.g., a developer solution, etchant, or the like) can be used or generated, or moisture from the outside can come in the touch sensor layer TSL. By disposing the touch buffer layer T-BUF on the encapsulation layer ENCAP and disposing the touch sensor layer TSL on the touch buffer layer T-BUF, such a chemical solution or moisture can be prevented from penetrating into the emission layer EL including an organic material during the process of manufacturing of the touch sensor layer TSL. Accordingly, the touch buffer layer T-BUF can prevent damage to the emission layer EL vulnerable to chemical solutions or moisture.

To prevent damage to the emission layer EL including an organic material vulnerable to a high temperature, the touch buffer layer T-BUF can be formed at a low temperature below a certain temperature (e.g., 100 degrees C.) and include an organic insulating material having a low dielectric constant of 1 to 3 (e.g., 2). For example, the touch buffer layer T-BUF can include an acrylic series, an epoxy series, a siloxane series material, or the like. When the display device 100 is bent, the encapsulation layer ENCAP can be damaged, and the touch sensor metal located on the touch buffer layer T-BUF can be broken. Even when the display device 100 is bent, the touch buffer layer T-BUF having a flattening performance with an organic insulating material can prevent damage to the encapsulation layer 350 and/or breakage of the metals (TSM and BRG) included in the touch sensor TS.

The protection layer PAC can be disposed such that it covers the touch sensor TS. The protection layer PAC can be an organic insulating layer.

Hereinafter, the stack-up structure of the transmissive area TA in the optical area OA is described with reference to FIG. 14.

Referring to FIG. 14, the substrate SUB and the insulating layers (MBUF, ABUF1, ABUF2, GI, ILD1, ILD2, PAS0, PLN (PLN1, PLN2, BANK, ENCAP (PAS1, PCL1, PCL2, PAS2, PAC) disposed in the non-transmissive area NTA can be equally disposed in the transmissive area TA in the optical area OA.

However, except for the insulating materials in the non-transmissive area NTA, material layers having electrical properties (e.g., one or more metal material layers, one or more semiconductor layers, and the like) may not be disposed in the transmissive area TA.

For example, metal material layers (ML1, ML2, GATE, GM, TM, SD1, SD2) related to the transistor and the semiconductor layer ACT may not be disposed in the transmissive area TA. The pixel electrode PE and the common electrode CE included in the light emitting element ED may not be disposed in the transmissive area TA. The emission layer EL can be disposed in the transmissive area TA. The touch sensor metals TSM and bridge metal BRG included in the touch sensor TS may not be disposed in the transmissive area TA.

Referring to FIG. 14, a lens CL can be disposed between the first encapsulating layer PCL1 and the second encapsulating layer PCL2 in the transmissive area TA.

The lens CL can be a refractive lens having a predetermined refractive index or a polarizing lens (e.g., a liquid crystal polarizing lens) capable of converting first circularly polarized light into second circularly polarized light or converting second circularly polarized light into first circularly polarized light.

The lens CL can be a Pancharatnam-Berry optical lens.

In an example where the lens CL is a polarizing lens, a first polarizing plate 910 and a second polarizing plate 920 can be disposed on the non-transmissive area NTA and the transmissive area TA.

For example, the first polarizing plate 910 can be a circular polarizing plate, and the second polarizing plate 920 can be a linear polarizing plate.

For example, the display device 100 can include a structure where the lens CL implemented using a polarizing lens, the first polarizing plate 910, and the second polarizing plate 920 overlap with each other in the transmissive area TA. Thereby, in the display device 100, the polarization of external light incident on optical electronic device 11 can be converted, and at the same time, the external light can be focused onto the transmissive area TA. In this way, the configuration of the display device 100 can improve the performance of the under-display optical device by efficiently guiding light to it without compromising the visual integrity of the display screen or the aesthetic design of the device.

The examples, aspects, and embodiments described above will be briefly described as follows.

According to the one or more example embodiments described herein, a display device can be provided that includes a display panel including an optical area including a plurality of transmissive areas and a plurality of light emitting areas, and a normal area disposed outside of the optical area and including a plurality of light emitting areas, an optical electronic device disposed under, or in a lower portion, of the display panel and overlapping with the optical area, and a plurality of lenses disposed in the optical area and overlapping with the plurality of transmissive areas, respectively.

In one or more aspects, the number of the plurality of lenses can be the same as the number of the plurality of transmissive areas.

In one or more aspects, the optical area can include a first transmissive area overlapping with a first lens among the plurality of lenses, a second transmissive area overlapping with a second lens among the plurality of lenses, and a first light emitting area disposed between the first transmissive area and the second transmissive area. In one or more aspects, at least a portion of the first light emitting area can overlap with at least one of the first lens and the second lens.

In one or more aspects, the first light emitting area can include a first area and a second area having a same area as the first area. In one or more aspects, the first area can overlap with at least a portion of the first lens, and the second area can overlap with at least a portion of the second lens.

In one or more aspects, the plurality of lenses can focus external light incident on the optical electronic device onto the plurality of transmissive areas, respectively.

In one or more aspects, the plurality of lenses can be refractive lenses having a predetermined refractive index.

In one or more aspects, the plurality of lenses can be polarizing lenses capable of converting first circularly polarized light into second circularly polarized light or converting the second circularly polarized light into the first circularly polarized light.

In one or more aspects, the polarizing lenses can be liquid crystal polarizing lenses capable of converting the first circularly polarized light into the second circularly polarized light and focusing the second circularly polarized light onto the plurality of transmissive areas, respectively.

In one or more aspects, the first circularly polarized light can be right-circularly polarized light, and the second circularly polarized light can be left-circularly polarized light.

In one or more aspects, the display device can further include a first polarizing plate disposed on the plurality of lenses, and a second polarizing plate disposed on the first polarizing plate.

In one or more aspects, the second polarizing plate can convert the external light into linearly polarized light, and the first polarizing plate can convert the linearly polarized light into the first circularly polarized light.

In one or more aspects, the first polarizing plate and the second polarizing plate can overlap with the optical area and the normal area, and the second polarizing plate can convert light output from the plurality of light emitting areas of one of the normal area and the optical area into linearly polarized light.

In one or more aspects, the display device can further include a substrate, a planarization layer disposed on the substrate, a plurality of first light emitting elements disposed on the planarization layer, and disposed in the plurality of light emitting areas of the optical area, respectively, and a plurality of second light emitting elements disposed on the planarization layer, and disposed in the plurality of light emitting areas of the normal area, respectively.

In one or more aspects, the display device can further include a first encapsulation layer and a second encapsulation layer disposed on the plurality of first light emitting elements and the plurality of second light emitting elements. In one or more aspects, the plurality of lenses can be disposed between the first encapsulation layer and the second encapsulation layer.

In one or more aspects, the plurality of lenses can be Pancharatnam-Berry optical lenses.

According to the one or more example embodiments described herein, a display device can be provided that includes a substrate on which a plurality of transmissive areas and a plurality of light emitting areas are disposed, a planarization layer disposed on the substrate, a plurality of light emitting elements disposed in the plurality of light emitting areas on the planarization layer, a first encapsulation layer disposed on the planarization layer and the plurality of light emitting elements, a plurality of lenses disposed on the first encapsulation layer, and overlapping with the plurality of transmissive areas, respectively, and a second encapsulation layer disposed on the first encapsulation layer and the plurality of lenses.

In one or more aspects, the display device can further include a first polarizing plate disposed on the second encapsulation layer, and a second polarizing plate disposed on the first polarizing plate.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the principles described herein can be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a display panel comprising an optical area including a plurality of transmissive areas and a plurality of light emitting areas, and a normal area disposed outside of the optical area and including a plurality of light emitting areas;
an optical electronic device disposed under or in a lower portion of the display panel and overlapping with the optical area; and
a plurality of lenses disposed in the optical area and overlapping with the plurality of transmissive areas.

2. The display device of claim 1, wherein a number of the plurality of lenses is equal to a number of the plurality of transmissive areas.

3. The display device of claim 1, wherein the optical area includes:
a first transmissive area overlapping with a first lens among the plurality of lenses,
a second transmissive area overlapping with a second lens among the plurality of lenses, and
a first light emitting area disposed between the first transmissive area and the second transmissive area, and
wherein at least a portion of the first light emitting area overlaps with at least one of the first lens and the second lens.

4. The display device of claim 3, wherein the first light emitting area includes a first area and a second area having a same area as the first area, and
wherein the first area of the first light emitting area overlaps with at least a portion of the first lens, and the second area of the first light emitting area overlaps with at least a portion of the second lens.

5. The display device of claim 1, wherein the plurality of lenses are configured to focus external light incident toward the optical electronic device onto the plurality of transmissive areas.

6. The display device of claim 5, wherein the plurality of lenses are refractive lenses having a predetermined refractive index.

7. The display device of claim 5, wherein the plurality of lenses are polarizing lenses configured to convert first circularly polarized light into second circularly polarized light or convert the second circularly polarized light into the first circularly polarized light.

8. The display device of claim 7, wherein the polarizing lenses are liquid crystal polarizing lenses configured to convert the first circularly polarized light into the second circularly polarized light and focus the second circularly polarized light onto the plurality of transmissive areas.

9. The display device of claim 7, wherein the first circularly polarized light is right-circularly polarized light, and the second circularly polarized light is left-circularly polarized light.

10. The display device of claim 7, further comprising:
a first polarizing plate disposed on the plurality of lenses; and
a second polarizing plate disposed on the first polarizing plate.

11. The display device of claim 10, wherein the second polarizing plate is configured to convert the external light into linearly polarized light, and
wherein the first polarizing plate is configured to convert the linearly polarized light into the first circularly polarized light.

12. The display device of claim 10, wherein the first polarizing plate and the second polarizing plate overlap with the optical area and the normal area, and
wherein the second polarizing plate is configured to convert light output from the plurality of light emitting areas of one of the normal area and the optical area into linearly polarized light.

13. The display device of claim 1, further comprising:
a substrate;
a planarization layer disposed on the substrate;
a plurality of first light emitting elements disposed on the planarization layer, and disposed in the plurality of light emitting areas of the optical area; and
a plurality of second light emitting elements disposed on the planarization layer, and disposed in the plurality of light emitting areas of the normal area.

14. The display device of claim 13, further comprising a first encapsulation layer and a second encapsulation layer disposed on the plurality of first light emitting elements and the plurality of second light emitting elements,
wherein the plurality of lenses are disposed between the first encapsulation layer and the second encapsulation layer.

15. The display device of claim 1, wherein the plurality of lenses are Pancharatnam-Berry optical lenses.

16. A display device comprising:
a plurality of transmissive areas and a plurality of light emitting areas disposed on a substrate;
a planarization layer disposed on the substrate;
a plurality of light emitting elements disposed in the plurality of light emitting areas on the planarization layer;
a first encapsulation layer disposed on the planarization layer and the plurality of light emitting elements;
a plurality of lenses disposed on the first encapsulation layer, and overlapping with the plurality of transmissive areas; and
a second encapsulation layer disposed on the first encapsulation layer and the plurality of lenses.

17. The display device of claim 16, further comprising:
a first polarizing plate disposed on the second encapsulation layer; and
a second polarizing plate disposed on the first polarizing plate.

18. A display device comprising:
a display panel including a first area having a first group of subpixels and a plurality of transmissive areas, and a second area disposed outside of the first area and having a second group of subpixels;
an optical electronic device overlapping with the first area;
a plurality of lenses disposed in the first area, at least one of the plurality of lenses overlapping with at least one subpixel among the first group of subpixels and at least one transmissive area among plurality of transmissive areas.

19. The display device of claim 18, wherein each of the plurality of lenses is configured to perform two operations of making external light incident on the display device spin in an opposite direction and bending the external light to focus at a single point.

20. The display device of claim 18, wherein an interface between two adjacent lenses among the plurality of lenses overlaps with at least one subpixel among the first group of subpixels.
